(19) United States
(12) Patent Application Publication
(10) Pub. No.: US 2026/0353766 A1
(43) Pub. Date: Nov. 5, 2026

(54) SEMICONDUCTOR DEVICE

(71) Applicants: Kabushiki Kaisha Toshiba, Kawasaki-shi, Kanagawa (JP); Toshiba Electronic Devices & Storage Corporation, Kawasaki-shi, Kanagawa (JP)

(72) Inventors: Takahiro OGATA, Kobe Hyogo (JP); Teruyuki OHASHI, Kawasaki Kanagawa (JP); Shunsuke ASABA, Himeji Hyogo (JP); Hiroshi KONO, Himeji Hyogo (JP)

(21) Appl. No.: 19/487,973

(22) PCT Filed: Apr. 1, 2024
(86) PCT No.: PCT/JP2024/013492

§ 371 Date: Nov. 25, 2025

(30) Foreign Application Priority Data
Jul. 13, 2023 (JP) 2023-115348

(51) Int. Cl. H10D 84/00; H10D 8/00; H10D 8/60; H10D 30/66; H10D 62/10; H10D 62/60; H10D 62/832; H10D 89/60

(52) U.S. Cl. CPC H10D 84/143; H10D 8/411; H10D 8/60; H10D 30/66; H10D 62/126; H10D 62/60; H10D 62/8325; H10D 84/146; H10D 89/611

(57) ABSTRACT

A semiconductor device of an embodiment includes a transistor region and a diode region. The transistor region includes a first silicon carbide region of n-type having a first portion in contact with a first face, a plurality of second silicon carbide regions of p-type, a third silicon carbide region of n-type, a plurality of fourth silicon carbide regions of p-type connecting the second silicon carbide regions, a first electrode, a second electrode, and a gate electrode. The diode region includes a first silicon carbide region of n-type having a second portion in contact with the first face, a fifth silicon carbide region of p-type, a plurality of sixth silicon carbide regions of p-type connecting the fifth silicon carbide regions, a first electrode, and a second electrode. A seventh silicon carbide region connecting the third silicon carbide region and the fifth silicon carbide region is further included.

### TECHNICAL FIELD

Embodiments described herein relate generally to a semiconductor device.

### BACKGROUND ART

One example of a material for a semiconductor device is silicon carbide. Silicon carbide has physical properties superior to those of silicon, including a band gap approximately three times wider, a breakdown field strength approximately ten times higher, and a thermal conductivity approximately three times greater. By utilizing these characteristics, for example, a metal oxide semiconductor field effect transistor (MOSFET) capable of operating at a high breakdown voltage, a low loss, and a high temperature can be realized.

A vertical MOSFET using silicon carbide includes a pn junction diode as a built-in diode. For example, a MOSFET is used as a switching element connected to an inductive load. In this case, even when the MOSFET is off, it is possible to allow a reflux current to flow by using the built-in diode.

However, when a reflux current is caused to flow using a body diode, there is a problem in that stacking faults grow in a silicon carbide layer due to carrier recombination energy, resulting in an increase in on-resistance of the MOSFET. An increase in on-resistance of the MOSFET leads to a decrease in reliability of the MOSFET. For example, by providing a Schottky barrier diode (SBD) that operates in a unipolar manner as a built-in diode in the MOSFET, it is possible to suppress the growth of the stacking faults in the silicon carbide layer. The reliability of the MOSFET is improved by providing an SBD as a built-in diode in the MOSFET.

A large surge current may flow instantaneously through the MOSFET beyond the steady state. When a large surge current flows, a large surge voltage is applied, heat is generated, and the MOSFET is destroyed. The maximum allowable peak current value (I_{FSM}) of the surge current tolerated by the MOSFET is referred to as surge current tolerance. In the MOSFET provided with an SBD, it is desirable to improve the surge current tolerance.

### CITATION LIST

### Patent Literature

PATENT LITERATURE 1: JP 2023-77119 A

### SUMMARY OF THE INVENTION

### Problem to be Solved by the Invention

An object of the present invention is to provide a semiconductor device with improved surge current tolerance.

### Means for Solving Problem

A semiconductor device of an embodiment includes a plurality of transistor regions and a plurality of diode regions alternately disposed in a first direction, in which the transistor region includes: a silicon carbide layer having a first face and a second face facing the first face, the silicon carbide layer including a first silicon carbide region of n-type having a plurality of first portions that are in contact with the first face, extend in a second direction orthogonal to the first direction, and are disposed in the first direction, a plurality of second silicon carbide regions of p-type provided between the first silicon carbide region and the first face, extending in the second direction, and disposed in the first direction, a third silicon carbide region of n-type provided between the second silicon carbide regions and the first face, and a plurality of fourth silicon carbide regions of p-type provided between the first silicon carbide region and the first face, disposed in the second direction, and connecting two adjacent second silicon carbide regions; a first electrode in contact with the first portions, the second silicon carbide regions, the third silicon carbide region, and the fourth silicon carbide regions; a second electrode in contact with the second face; a plurality of gate electrodes facing the second silicon carbide regions, extending in the second direction, and disposed in the first direction; and a gate insulating layer provided between the gate electrodes and the second silicon carbide regions, the diode region includes: the silicon carbide layer including the first silicon carbide region of n-type having a plurality of second portions in contact with the first face and extending in the second direction, a plurality of fifth silicon carbide regions of p-type provided between the first silicon carbide region and the first face, extending in the second direction, and disposed in the first direction, and a plurality of sixth silicon carbide regions of p-type provided between the first silicon carbide region and the first face, disposed in the second direction, and connecting two adjacent fifth silicon carbide regions; the first electrode in contact with the second portions, the fifth silicon carbide regions, and the sixth silicon carbide regions; and the second electrode, and the silicon carbide layer further includes a plurality of seventh silicon carbide regions of p-type provided between the first silicon carbide region and the first face, disposed in the second direction, and connecting adjacent second silicon carbide regions and adjacent fifth silicon carbide regions.

### BRIEF DESCRIPTION OF THE DRAWINGS

FIG. 1 is a schematic top view of a semiconductor device of a first embodiment.

FIG. 2 is a schematic cross-sectional view of a part of the semiconductor device of the first embodiment.

FIG. 3 is a schematic top view of a part of the semiconductor device of the first embodiment.

FIG. 4 is an enlarged schematic cross-sectional view of a part of the semiconductor device of the first embodiment.

FIG. 5 is an enlarged schematic cross-sectional view of a part of the semiconductor device of the first embodiment.

FIG. 6 is a schematic cross-sectional view of a part of the semiconductor device of the first embodiment.

FIG. 7 is a schematic top view of a part of the semiconductor device of the first embodiment.

FIG. 8 is an enlarged schematic cross-sectional view of a part of the semiconductor device of the first embodiment.

FIG. 9 is an enlarged schematic cross-sectional view of a part of the semiconductor device of the first embodiment.

FIG. 10 is a schematic cross-sectional view of a part of the semiconductor device of the first embodiment.

FIG. 11 is a schematic top view of a part of the semiconductor device of the first embodiment.

FIG. 12 is an enlarged schematic cross-sectional view of a part of the semiconductor device of the first embodiment.

FIG. 13 is an enlarged schematic cross-sectional view of a part of the semiconductor device of the first embodiment.

FIG. 14 is a schematic top view of the semiconductor device of the first embodiment.

FIG. 15 is a schematic top view of a semiconductor device of a first comparative example.

FIG. 16 is a schematic cross-sectional view of the semiconductor device of the first comparative example.

FIG. 17 is an equivalent circuit diagram of the semiconductor device of the first comparative example.

FIG. 18 is an explanatory view of the function and effect of the semiconductor device of the first embodiment.

FIG. 19 is an explanatory view of the function and effect of the semiconductor device of the first embodiment.

FIG. 20 is an explanatory view of the function and effect of the semiconductor device of the first embodiment.

FIG. 21 is a schematic top view of a semiconductor device of a third comparative example.

FIG. 22 is an explanatory view of the function and effect of the semiconductor device of the first embodiment.

FIG. 23 is an explanatory view of the function and effect of the semiconductor device of the first embodiment.

FIG. 24 is a schematic cross-sectional view of a semiconductor device according to a first modification of the first embodiment.

FIG. 25 is a schematic cross-sectional view of the semiconductor device according to the first modification of the first embodiment.

FIG. 26 is a schematic cross-sectional view of a part of a semiconductor device of a second embodiment.

FIG. 27 is a schematic top view of a part of the semiconductor device of the second embodiment.

FIG. 28 is a schematic cross-sectional view of a part of a semiconductor device of the second embodiment.

FIG. 29 is a schematic top view of a part of the semiconductor device of the second embodiment.

FIG. 30 is a schematic cross-sectional view of a part of a semiconductor device of the second embodiment.

FIG. 31 is a schematic top view of a part of the semiconductor device of the second embodiment.

### EMBODIMENT(S) FOR CARRYING OUT THE INVENTION

Hereinafter, embodiments of the present invention will be described with reference to the drawings. Note that, in the following description, the same or similar members and the like are denoted by the same reference numerals, and the descriptions of the members and the like once described may be appropriately omitted.

In addition, in the following description, the notations of n⁺, n, n⁻, p⁺, p, and p⁻ indicate relative levels of impurity concentrations in respective conductive types. That is, n⁺ indicates an n-type impurity concentration relatively higher than that of n, and n⁻ indicates an n-type impurity concentration relatively lower than that of n. In addition, p⁺ indicates a p-type impurity concentration relatively higher than that of p, and p⁻ indicates a p-type impurity concentration relatively lower than that of p. Note that an n⁺-type and an n⁻-type may be simply referred to as an n-type, and a p⁺-type and a p⁻-type may be simply referred to as a p-type.

An impurity concentration can be measured by, for example, secondary ion mass spectrometry (SIMS). In addition, a relative level of the impurity concentration can also be determined from a level of a carrier concentration obtained by, for example, scanning capacitance microscopy (SCM). In addition, distances such as a depth and a thickness of an impurity region can be determined, for example, from an image obtained by a scanning electron microscope (SEM) or by using SIMS.

In the present specification, the impurity concentration in the semiconductor region means the maximum impurity concentration in the semiconductor region unless otherwise stated.

### First Embodiment

A semiconductor device of a first embodiment includes a plurality of transistor regions and a plurality of diode regions alternately disposed in a first direction. The transistor region includes a silicon carbide layer having a first face and a second face facing the first face, the silicon carbide layer including a first silicon carbide region of n-type having a plurality of first portions that are in contact with the first face, extend in a second direction orthogonal to the first direction, and are disposed in the first direction, a plurality of second silicon carbide regions of p-type provided between the first silicon carbide region and the first face, extending in the second direction, and disposed in the first direction, a third silicon carbide region of n-type provided between the second silicon carbide regions and the first face, and a plurality of fourth silicon carbide regions of p-type provided between the first silicon carbide region and the first face, disposed in the second direction, and connecting two adjacent second silicon carbide regions; a first electrode in contact with the first portions, the second silicon carbide regions, the third silicon carbide region, and the fourth silicon carbide regions; a second electrode in contact with the second face; a plurality of gate electrodes facing the second silicon carbide regions, extending in the second direction, and disposed in the first direction; and a gate insulating layer provided between the gate electrodes and the second silicon carbide regions. The diode region includes the silicon carbide layer including the first silicon carbide region of n-type having a plurality of second portions in contact with the first face and extending in the second direction, a plurality of fifth silicon carbide regions of p-type provided between the first silicon carbide region and the first face, extending in the second direction, and disposed in the first direction, and a plurality of sixth silicon carbide regions of p-type provided between the first silicon carbide region and the first face, disposed in the second direction, and connecting two adjacent fifth silicon carbide regions; the first electrode in contact with the second portions, the fifth silicon carbide regions, and the sixth silicon carbide regions; and the second electrode. The silicon carbide layer further includes a plurality of seventh silicon carbide regions of p-type provided between the first silicon carbide region and the first face, disposed in the second direction, and connecting adjacent second silicon carbide regions and adjacent fifth silicon carbide regions.

The semiconductor device of the first embodiment is a vertical MOSFET 100 of a planar gate type using silicon carbide. The MOSFET 100 of the first embodiment is, for example, a double implantation MOSFET (DIMOSFET) in which a body region and a source region are formed by ion implantation. In addition, the semiconductor device of the first embodiment includes a Schottky barrier diode (SBD) as a built-in diode. The MOSFET 100 is a MOSFET of a vertical n-channel type using electrons as carriers.

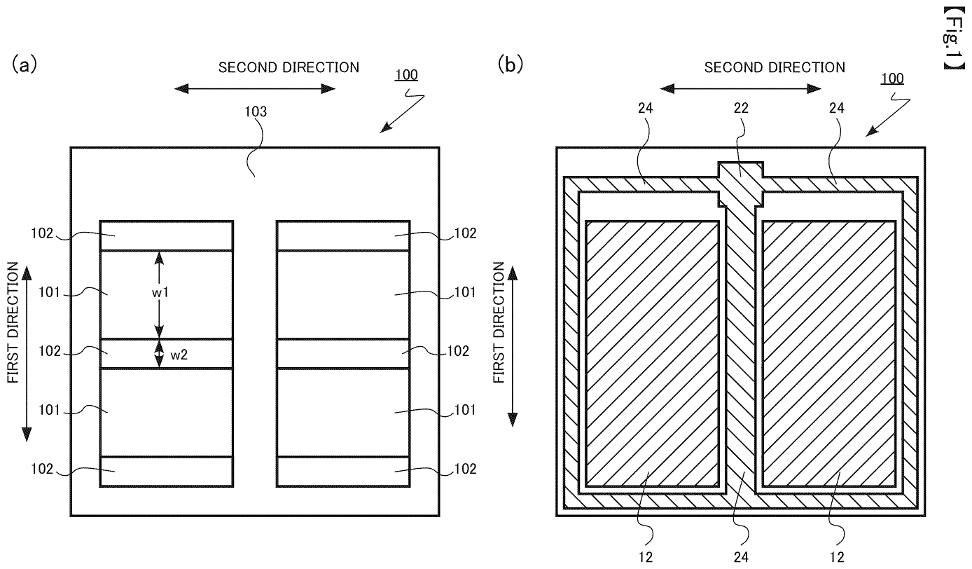

FIG. 1(a) and 1(b) are schematic top views of the semiconductor device of the first embodiment. FIG. 1(a) is an arrangement view of the respective regions included in the MOSFET 100. FIG. 1(b) is a view illustrating patterns of electrodes and wirings on an upper face of the MOSFET 100.

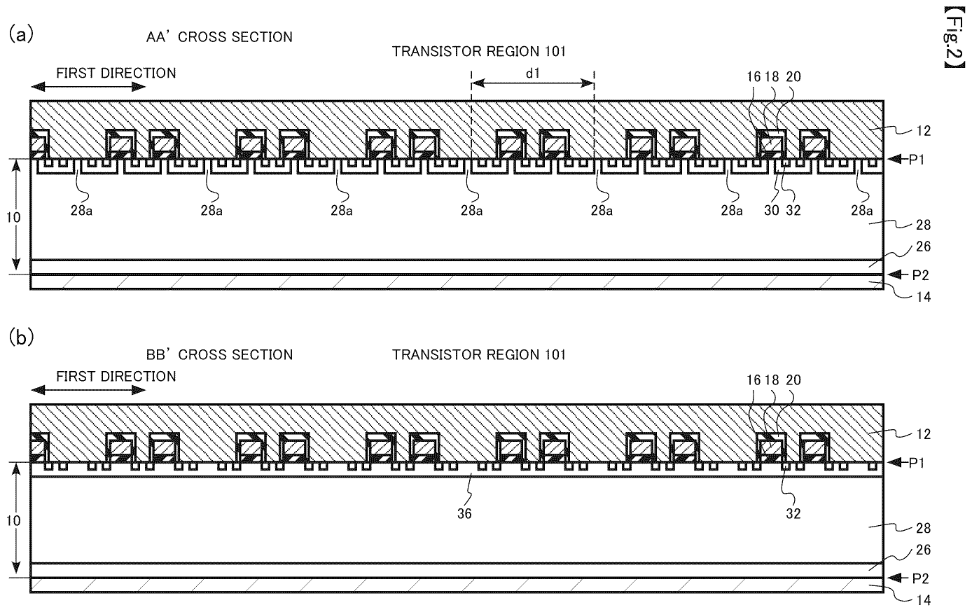

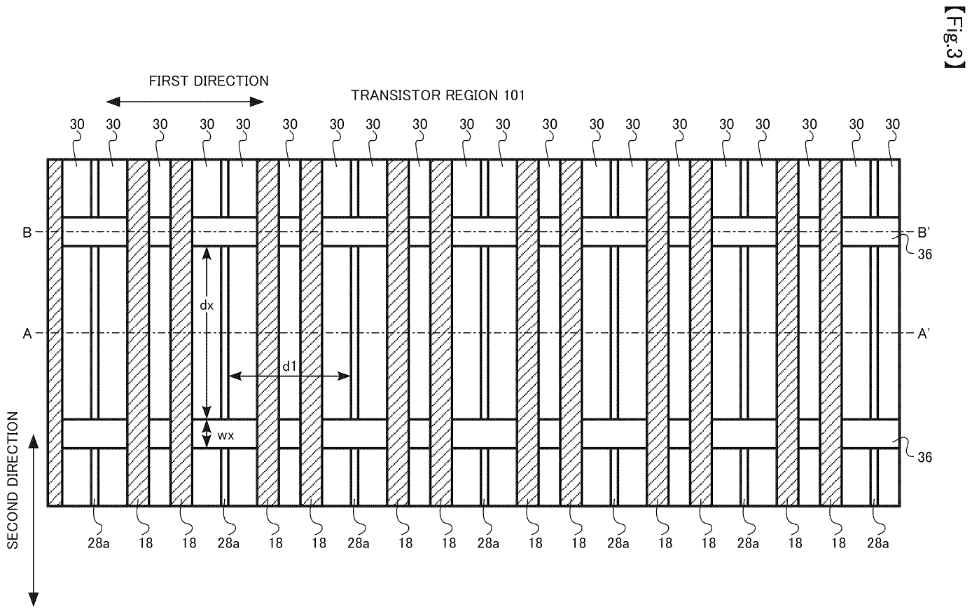

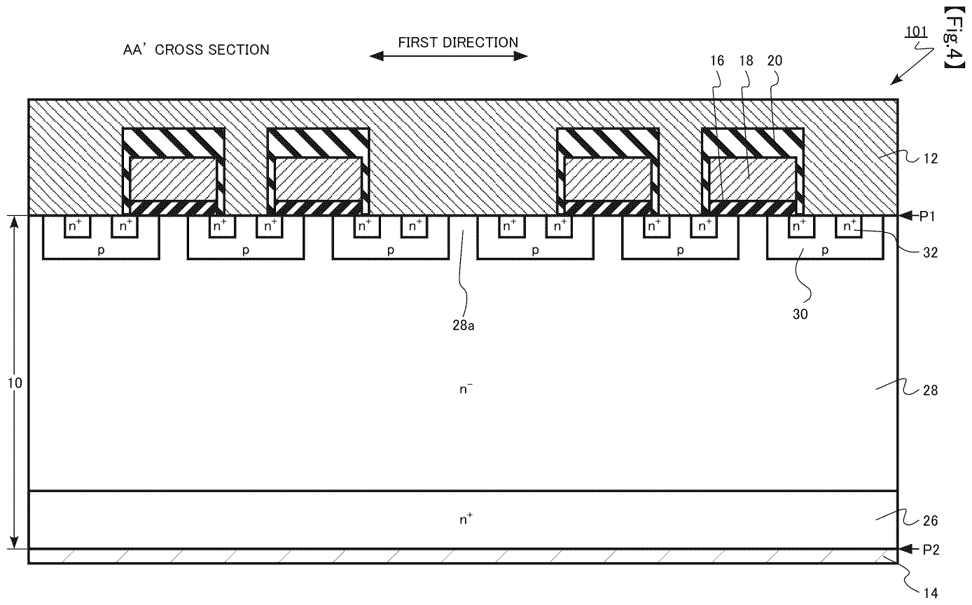

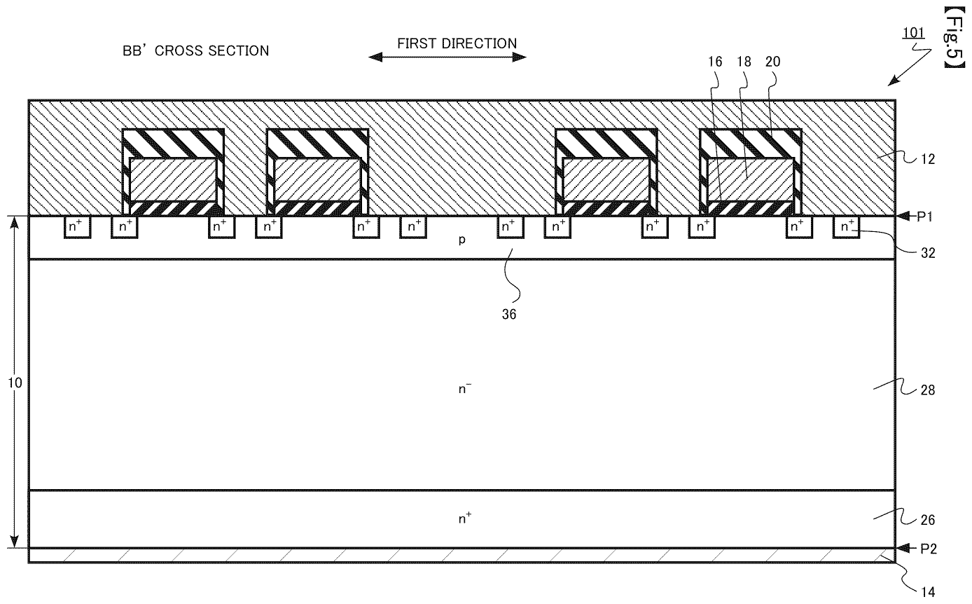

FIG. 2(a) and 2(b) are schematic cross-sectional views of a part of the semiconductor device of the first embodiment. FIG. 3 is a schematic top view of a part of the semiconductor device of the first embodiment. FIGS. 4 and 5 are enlarged schematic cross-sectional views of a part of the semiconductor device of the first embodiment.

FIG. 2(a) is a cross section taken along line AA′ of FIG. 3. FIG. 2(b) is a cross section taken along line BB′ of FIG. 3. FIG. 4 is an enlarged schematic cross-sectional view of a part of FIG. 2(a). FIG. 5 is an enlarged schematic cross-sectional view of a part of FIG. 2(b).

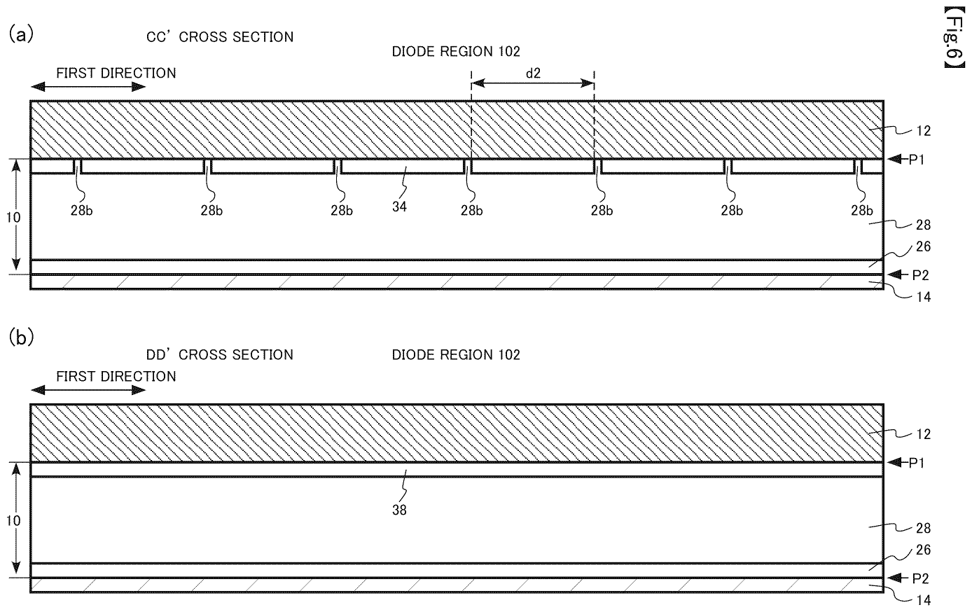

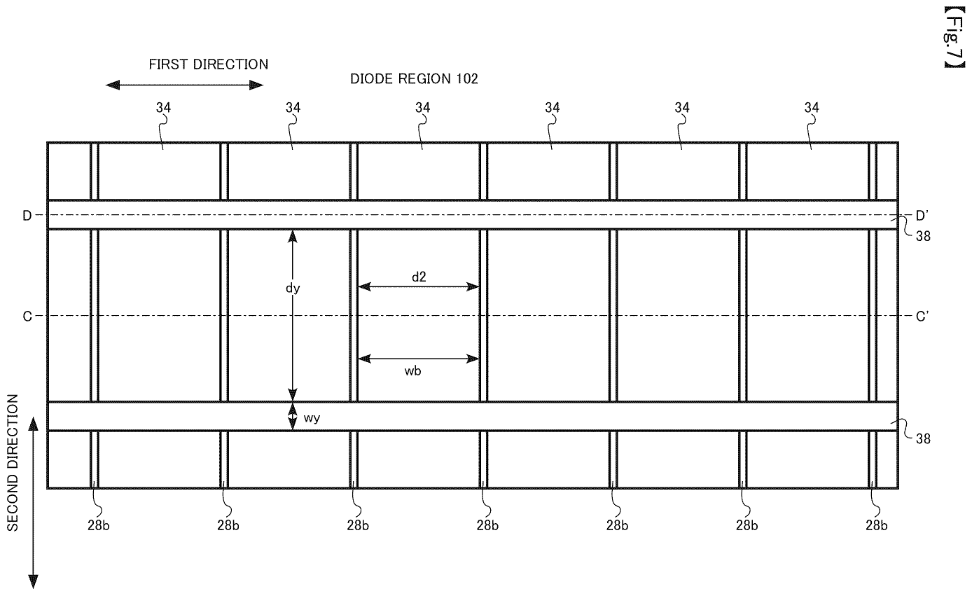

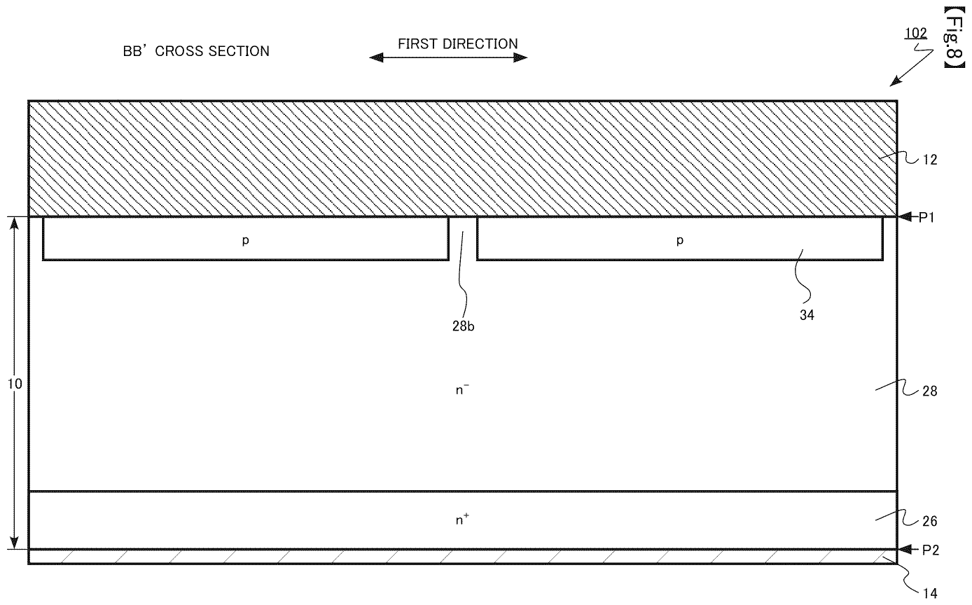

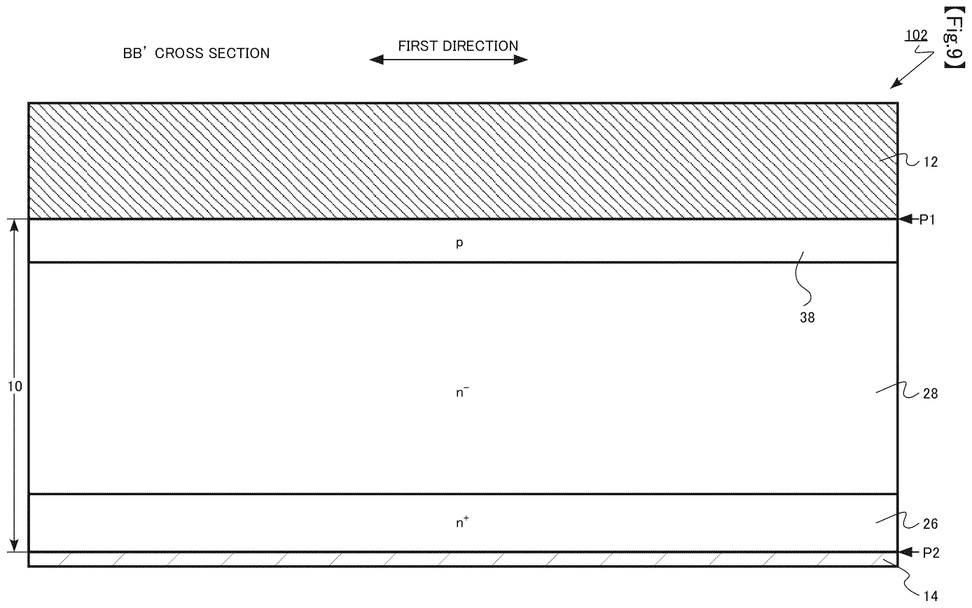

FIG. 6(a) and 6(b) are schematic cross-sectional views of a part of the semiconductor device of the first embodiment. FIG. 7 is a schematic top view of a part of the semiconductor device of the first embodiment. FIGS. 8 and 9 are enlarged schematic cross-sectional views of a part of the semiconductor device of the first embodiment.

FIG. 6(a) is a cross section taken along line CC′ of FIG. 7. FIG. 6(b) is a cross section taken along line DD′ of FIG. 7. FIG. 8 is an enlarged schematic cross-sectional view of a part of FIG. 6(a). FIG. 9 is an enlarged schematic cross-sectional view of a part of FIG. 6(b).

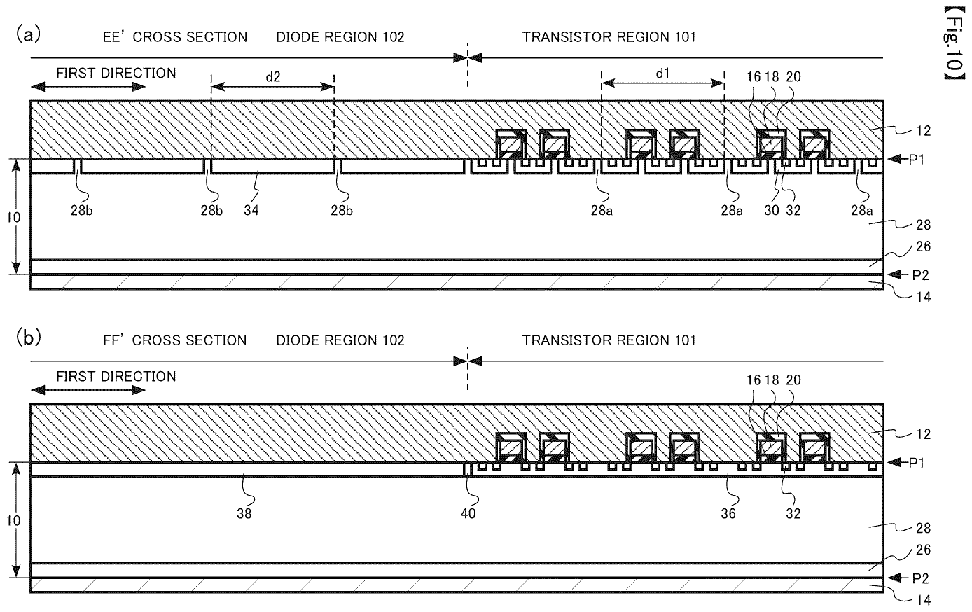

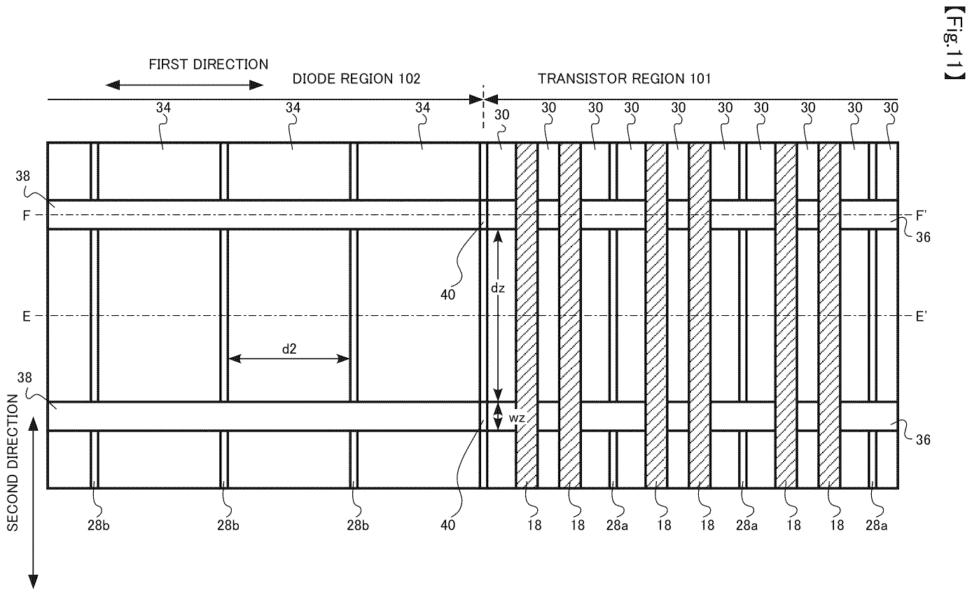

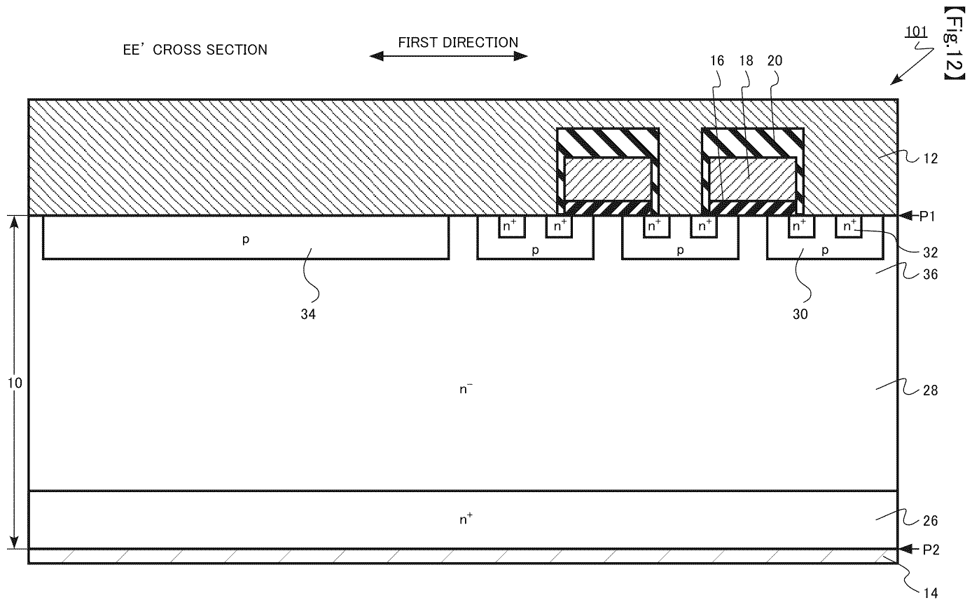

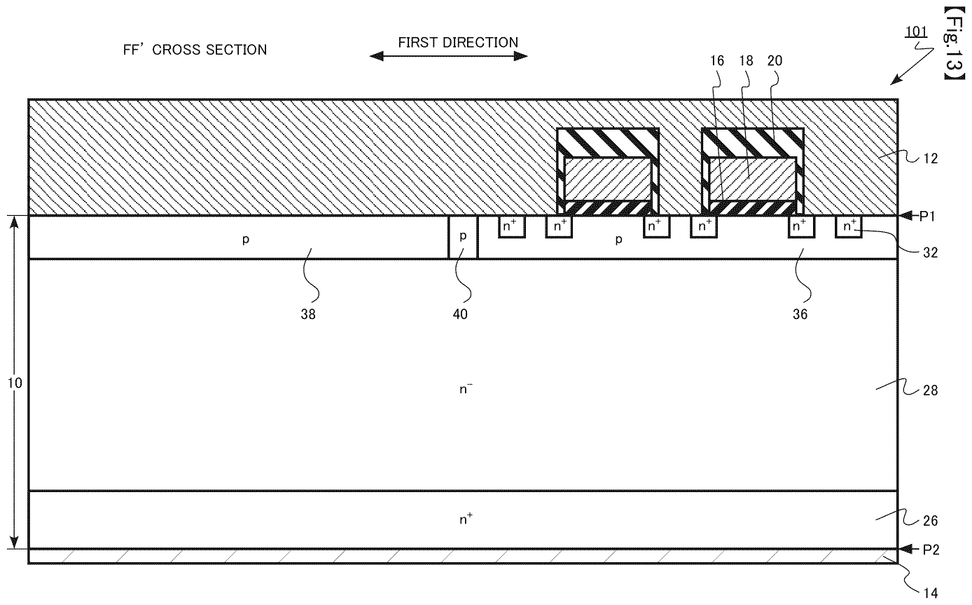

FIG. 10(a) and 10(b) are schematic cross-sectional views of a part of the semiconductor device of the first embodiment. FIG. 11 is a schematic top view of a part of the semiconductor device of the first embodiment. FIGS. 12 and 13 are enlarged schematic cross-sectional views of a part of the semiconductor device of the first embodiment.

FIG. 10(a) is a cross section taken along line EE′ of FIG. 11. FIG. 10(b) is a cross section taken along line FF′ of FIG. 11. FIG. 12 is an enlarged schematic cross-sectional view of a part of FIG. 10(a). FIG. 13 is an enlarged schematic cross-sectional view of a part of FIG. 10(b).

As illustrated in FIG. 1(a), the MOSFET 100 includes a plurality of transistor regions 101, a plurality of diode regions 102, and a termination region 103.

The plurality of transistor regions 101 and the plurality of diode regions 102 are alternately disposed in a first direction parallel to a first face P1. The transistor region 101 is, for example, sandwiched between two diode regions 102 in the first direction. The diode region 102 is, for example, sandwiched between two transistor regions 101 in the first direction.

A width (w1 in FIG. 1(a)) of the transistor region 101 in the first direction is, for example, greater than a width (w2 in FIG. 1(a)) of the diode region 102 in the first direction.

FIG. 1(a) illustrates a case where two transistor regions 101 and three diode regions 102 are disposed in the first direction. However, the numbers of the transistor regions 101 and the diode regions 102 are not limited to these numbers.

A MOSFET and an SBD are provided in the transistor region 101. An SBD is provided in the diode region 102. A MOSFET is not provided in the diode region 102.

The termination region 103 surrounds the transistor region 101 and the diode region 102. The termination region 103 is provided with a structure for improving a breakdown voltage of the MOSFET 100. The structure for improving the breakdown voltage of the MOSFET 100 is, for example, a RESURF or a guard ring.

The MOSFET 100 includes a silicon carbide layer 10, a source electrode 12 (first electrode), a drain electrode 14 (second electrode), a gate insulating layer 16, a gate electrode 18, an interlayer insulating layer 20, a gate electrode pad 22, and a gate wiring 24.

The silicon carbide layer 10 includes a drain region 26 of n+-type, a drift region 28 of n⁻-type (first silicon carbide region), a body region 30 of p-type (second silicon carbide region), a source region 32 of n⁺-type (third silicon carbide region), an anode region 34 of p-type (fifth silicon carbide region), a first bridging region 36 of p-type (fourth silicon carbide region), a second bridging region 38 of p-type (sixth silicon carbide region), and a third bridging region 40 of p-type (seventh silicon carbide region).

The drift region 28 has a plurality of first portions 28a and a plurality of second portions 28b.

FIG. 2(a), 2(b), 3, 4, and 5 are views illustrating the transistor region 101.

As illustrated in FIG. 2(a), 2(b), 3, 4, and 5, the transistor region 101 includes a silicon carbide layer 10, a source electrode 12 (first electrode), a drain electrode 14 (second electrode), a gate insulating layer 16, a gate electrode 18, and an interlayer insulating layer 20. The silicon carbide layer 10 of the transistor region 101 includes a drain region 26 of n⁺-type, a drift region 28 of n⁻-type (first silicon carbide region), a plurality of body regions 30 of p-type (second silicon carbide region), a plurality of source regions 32 of n⁺-type (third silicon carbide region), and a plurality of first bridging regions 36 of p-type (fourth silicon carbide region).

Note that FIG. 3 illustrates only patterns of the drift region 28, the body region 30, the first bridging region 36, and the gate electrode 18.

In the transistor region 101, the source electrode 12, the first portion 28a of the drift region 28, the drain region 26, and the drain electrode 14 constitute an SBD.

In addition, the source electrode 12, the body region 30, the drift region 28, the drain region 26, and the drain electrode 14 constitute a pn junction diode.

The silicon carbide layer 10 is provided between the source electrode 12 and the drain electrode 14. The silicon carbide layer 10 is provided between the gate electrode 18 and the drain electrode 14. The silicon carbide layer 10 is single crystal SiC. The silicon carbide layer 10 is, for example, 4H—SiC.

The silicon carbide layer 10 includes a first face (“P1” in FIG. 2(a) and 2(b)) and a second face (“P2” in FIG. 2(a) and 2(b)). The first face P1 and the second face P2 face each other. Hereinafter, the first face may be referred to as a surface, and the second face may be referred to as a back surface. Note that, hereinafter, the term “depth” refers to a depth based on the first face.

The first face P1 is, for example, a face inclined at equal to or more than 0° and equal to or less than 8° with respect to a (0001) face. In addition, the second face P2 is, for example, a face inclined at equal to or more than 0° and equal to or less than 8° with respect to a (000-1) face. The (0001) face is referred to as a silicon face. The (000-1) face is referred to as a carbon face.

The drain region 26 of n⁺-type is provided on a back surface of the silicon carbide layer 10. The drain region 26 contains, for example, nitrogen (N) as n-type impurities. An n-type impurity concentration in the drain region 26 is, for example, equal to or more than 1×10¹⁸ cm⁻³ and equal to or less than 1×10²¹ cm⁻³.

The drift region 28 of n⁻-type is provided between the drain region 26 and the first face P1. The drift region 28 is provided between the source electrode 12 and the drain electrode 14. The drift region 28 is provided between the gate electrode 18 and the drain electrode 14.

The drift region 28 is provided on the drain region 26. The drift region 28 contains, for example, nitrogen (N) as n-type impurities. An n-type impurity concentration in the drift region 28 is lower than the n-type impurity concentration in the drain region 26. The n-type impurity concentration in the drift region 28 is for example, equal to or more than 4×10¹⁴ cm⁻³ and equal to or less than 1×10¹⁷cm⁻³. A thickness of the drift region 28 is, for example, equal to or more than 5 μm and equal to or less than 150 μm.

The drift region 28 has a plurality of first portions 28a. The first portions 28a are in contact with the first face P1.

The first portions 28a extend in a second direction orthogonal to the first direction. The first portion 28a is repeatedly disposed in the first direction. The first portions 28a are sandwiched between two body regions 30 adjacent in the first direction.

The first portion 28a functions as an n-type semiconductor region of the SBD.

The body region 30 of p-type is provided between the drift region 28 and the first face P1. The body region 30 extends in the second direction. The body region 30 is repeatedly disposed in the first direction.

A part of the body region 30 functions as a channel region of the MOSFET 100. The body region 30 functions as a p-type semiconductor region of a pn junction diode.

The body region 30 includes, for example, a low concentration portion and a high concentration portion.

The high concentration portion is provided between the low concentration portion and the first face P1. The p-type impurity concentration in the high concentration portion is higher than the p-type impurity concentration in the low concentration portion.

The body region 30 contains, for example, aluminum (Al) as p-type impurities. A p-type impurity concentration

in the body region 30 is, for example, equal to or more than 1×10¹⁶ cm⁻³ and equal to or less than 1×10²¹ cm⁻³. The p-type impurity concentration in the body region 30 is defined by the p-type impurity concentration at a position half the depth of the body region 30.

The depth of the body region 30 is, for example, equal to or more than 0.3 μm and equal to or less than 1.0 μm.

The body region 30 is fixed to an electric potential of the source electrode 12.

The source region 32 of n⁺-type is provided between the body region 30 and the first face P1. The source region 32 is provided between the body region 30 and the first face P1. The source region 32 extends, for example, in the second direction.

The source region 32 contains, for example, phosphorus (P) as n-type impurities. An n-type impurity concentration in the source region 32 is higher than the n-type impurity concentration in the drift region 28.

The n-type impurity concentration in the source region 32 is, for example, equal to or more than 1×10¹⁸ cm⁻³ and equal to or less than 1×10²¹ cm⁻³. A depth of the source region 32 is shallower than the depth of the body region 30. The depth of the source region 32 is, for example, equal to or more than 0.1 μm and equal to or less than 0.3 μm.

The first bridging region 36 of p-type is provided between the drift region 28 and the first face P1. The first bridging region 36 is repeatedly disposed in the second direction.

The first bridging region 36 connects two body regions 30 adjacent in the first direction. The first bridging region 36 extends, for example, in the first direction. The first bridging region 36 intersects, for example, the body region 30. The first bridging region 36 overlaps, for example, the body region 30.

The first bridging region 36 divides the first portion 28a extending in the second direction. The first bridging region 36 connects two adjacent body regions 30 spaced apart with the first portion 28a of n-type interposed therebetween by a silicon carbide region of p-type.

A distance (dx in FIG. 3) in the second direction between two first bridging regions 36 adjacent in the second direction is, for example, less than a width (w1 in FIG. 1(a)) of the transistor region 101 in the first direction. The distance dx in the second direction between two adjacent first bridging regions 36 is, for example, equal to or more than 10 μm and equal to or less than 200 μm.

A width (wx in FIG. 3) of the first bridging region 36 in the second direction is, for example, less than a first distance (d1 in FIG. 2(a) and 3) between two adjacent first portions 28a in the first direction. The width (wx in FIG. 3) of the first bridging region 36 in the second direction is, for example, equal to or less than one-half of the first distance (d1 in FIG. 2(a) and 3) between two adjacent two adjacent first portions 28a in the first direction.

The first distance d1 in the first direction between two adjacent first portions 28a is, for example, equal to or more than 3 μm and equal to or less than 30 μm. The width wx of the first bridging region 36 in the second direction is, for example, equal to or more than 1 μm and equal to or less than 10 μm.

The first bridging region 36 contains, for example, aluminum (Al) as p-type impurities. A p-type impurity concentration in the first bridging region 36 is, for example, equal to or more than 1×10¹⁶ cm⁻³ and equal to or less than 1×10²¹ cm⁻³.

The p-type impurity concentration in the first bridging region 36 is, for example, substantially the same as the p-type impurity concentration in the body region 30. Note that the p-type impurity concentration in the first bridging region 36 is defined by the p-type impurity concentration at a position half the depth of the first bridging region 36.

The depth of the first bridging region 36 is, for example, equal to or more than 0.3 μm and equal to or less than 1.0 μm. The depth of the first bridging region 36 is, for example, substantially the same as the depth of the body region 30.

An electric potential of the first bridging region 36 is fixed to the electric potential of the source electrode 12.

Note that, although FIG. 3 illustrates a case where two first bridging regions 36 are disposed in the second direction, the number of first bridging regions 36 may be equal to or greater than three.

The gate electrode 18 is provided on the first face P1 of the silicon carbide layer 10. The gate electrode 18 extends in the second direction parallel to the first face P1 and orthogonal to the first direction. A plurality of gate electrodes 18 are disposed in parallel in the first direction. The gate electrode 18 has a so-called stripe shape.

The gate electrode 18 is a conductive layer. The gate electrode 18 is, for example, polycrystalline silicon containing p-type impurities or n-type impurities.

The gate electrode 18 faces, for example, a portion in contact with the first face P1 of the body region 30. The gate electrode 18 faces, for example, a portion in contact with the first face P1 of the drift region 28.

The gate insulating layer 16 is provided between the gate electrode 18 and the body region 30. The gate insulating layer 16 is provided between the gate electrode 18 and the drift region 28.

The gate insulating layer 16 is, for example, silicon oxide. For example, a high-k insulating material (high dielectric constant insulating material) can be applied to the gate insulating layer 16.

The interlayer insulating layer 20 is provided on the gate electrode 18 and the silicon carbide layer 10.

The interlayer insulating layer 20 is provided between the gate electrode 18 and the source electrode 12. The interlayer insulating layer 20 is, for example, silicon oxide.

The source electrode 12 is provided on the first face P1 of the silicon carbide layer 10. The source electrode 12 is in contact with the first face P1.

The source electrode 12 is in contact with the first portion 28a of the drift region 28, the body region 30, the source region 32, and the first bridging region 36.

The source electrode 12 contains a metal. The metal forming the source electrode 12 has, for example, a stacked structure of titanium (Ti) and aluminum (Al).

The portion of the source electrode 12 in contact with the body region 30, the source region 32, and the first bridging region 36 is, for example, metal silicide.

The metal silicide is, for example, titanium silicide or nickel silicide. For example, metal silicide is not provided in a portion of the source electrode 12 in contact with the first portion 28a of the drift region 28.

The junction between the body region 30, the source region 32, and the first bridging region 36, and the source electrode 12 is, for example, an ohmic junction. The junction between the first portion 28a of the drift region 28 and the source electrode 12 is, for example, a Schottky junction.

The drain electrode 14 is provided on the second face P2 of the silicon carbide layer 10. The drain electrode 14 is in contact with the second face P2. The drain electrode 14 is in contact with the drain region 26.

The drain electrode 14 is, for example, a metal or a metal semiconductor compound. The drain electrode 14 contains, for example, at least one material selected from the group consisting of nickel silicide (NiSi), titanium (Ti), nickel (Ni), silver (Ag), and gold (Au).

The junction between the drain region 26 and the drain electrode 14 is, for example, an ohmic junction.

FIG. 6(a), 6(b), 7, 8, and 9 are views illustrating the diode region 102.

As illustrated in FIG. 6(a), 6(b), 7, 8, and 9, the diode region 102 includes the silicon carbide layer 10, the source electrode 12 (first electrode), and the drain electrode 14 (second electrode). The silicon carbide layer 10 of the diode region 102 includes a drain region 26 of n⁺-type, a drift region 28 of-type (first silicon carbide region), a plurality of anode regions 34 of p-type (fifth silicon carbide region), and a second bridging region 38 of p-type (sixth silicon carbide region).

Note that FIG. 7 illustrates only patterns of the drift region 28, the anode region 34, and the second bridging region 38.

In the diode region 102, the source electrode 12, the second portion 28b of the drift region 28, the drain region 26, and the drain electrode 14 constitute an SBD. In addition, the source electrode 12, the anode region 34, the drift region 28, the drain region 26, and the drain electrode 14 constitute a pn junction diode.

The drift region 28 has a plurality of second portions 28b. The second portions 28b are in contact with the first face P1.

The second portions 28b extend in the second direction. The second portion 28b is repeatedly disposed in the first direction. The second portions 28b are sandwiched between two anode regions 34 adjacent in the first direction.

The second portion 28b functions as an n-type semiconductor region of the SBD.

The anode region 34 of p-type is provided between the drift region 28 and the first face P1. The anode region 34 functions as a p-type semiconductor region of a pn junction diode.

The anode region 34 includes, for example, a low concentration portion and a high concentration portion.

The high concentration portion is provided between the low concentration portion and the first face P1. The p-type impurity concentration in the high concentration portion is higher than the p-type impurity concentration in the low concentration portion.

The anode region 34 contains, for example, aluminum (Al) as p-type impurities. A p-type impurity concentration in the anode region 34 is, for example, equal to or more than 1×10¹⁶ cm⁻³ and equal to or less than 1×10²¹ cm⁻³. Note that the p-type impurity concentration in the anode region 34 is defined by the p-type impurity concentration at a position half the depth of the anode region 34.

A width (wb in FIG. 7) of the anode region 34 in the first direction is, for example, greater than the width of the body region 30 in the first direction.

The depth of the anode region 34 is, for example, substantially the same as the depth of the body region 30. The depth of the anode region 34 is, for example, equal to or more than 0.3 μm and equal to or less than 1.0 μm.

The anode region 34 is fixed to the electric potential of the source electrode 12.

The second bridging region 38 of p-type is provided between the drift region 28 and the first face P1. The second bridging region 38 is repeatedly disposed in the second direction.

The second bridging region 38 connects two anode regions 34 adjacent in the first direction. The second bridging region 38 extends, for example, in the first direction. The second bridging region 38 intersects, for example, the anode region 34. The second bridging region 38 overlaps, for example, the anode region 34.

The second bridging region 38 divides the second portion 28b extending in the second direction. The second bridging region 38 connects two adjacent anode regions 34 spaced apart with the second portion 28b of n-type interposed therebetween by a silicon carbide region of p-type.

A distance (dy in FIG. 7) in the second direction between two adjacent second bridging regions 38 is, for example, less than the width (w1 in FIG. 1(a)) of the transistor region 101 in the first direction. The distance dy in the second direction between two adjacent second bridging regions 38 is, for example, equal to or more than 10 μm and equal to or less than 200 μm.

A width (wy in FIG. 7) of the second bridging region 38 in the second direction is, for example, less than a width (wb in FIG. 7) of the anode region 34 in the first direction. The width (wy in FIG. 7) of the second bridging region 38 in the second direction is, for example, equal to or less than one-half of the width (wb in FIG. 7) of the anode region 34 in the first direction.

In addition, the width (wy in FIG. 7) of the second bridging region 38 in the second direction is, for example, less than a second distance (d2 in FIG. 6(a) and 7) between two adjacent second portions 28b in the first direction. The width (wy in FIG. 7) of the second bridging region 38 in the second direction is, for example, equal to or less than one-half of the second distance (d2 in FIG. 6(a)) between two adjacent second portions 28b in the first direction.

The second distance d2 in the first direction between two adjacent second portions 28b is, for example, equal to or more than 3 μm and equal to or less than 30 μm. The width wy of the second bridging region 38 in the second direction is, for example, equal to or more than 1 μm and equal to or less than 10 μm.

The second distance (d2 in FIG. 6(a) and 7) in the first direction between two adjacent second portions 28b is, for example, substantially equal to the first distance (d1 in FIG. 2(a)) in the first direction between two adjacent first portions 28a.

The second bridging region 38 contains, for example, aluminum (Al) as p-type impurities. A p-type impurity concentration in the second bridging region 38 is, for example, equal to or more than 1×10¹⁶ cm⁻³ and equal to or less than 1×10²¹ cm⁻³.

The p-type impurity concentration in the second bridging region 38 is, for example, substantially the same as the p-type impurity concentration in the anode region 34. The p-type impurity concentration in the second bridging region 38 is, for example, substantially the same as the p-type impurity concentration in the first bridging region 36. Note that the p-type impurity concentration in the second bridging region 38 is defined by the p-type impurity concentration at a position half the depth of the second bridging region 38.

The depth of the second bridging region 38 is, for example, equal to or more than 0.3 μm and equal to or less than 1.0 μm. The depth of the second bridging region 38 is, for example, substantially the same as the depth of the anode region 34. The depth of the second bridging region 38 is, for example, substantially the same as the depth of the first bridging region 36.

An electric potential of the second bridging region 38 is fixed to the electric potential of the source electrode 12.

Note that, although FIG. 7 illustrates a case where two second bridging regions 38 are disposed in the second direction, the number of second bridging regions 38 may be equal to or greater than three.

The source electrode 12 is provided on the first face P1 of the silicon carbide layer 10. The source electrode 12 is in contact with the first face P1.

The source electrode 12 is in contact with the second portion 28b of the drift region 28, the anode region 34, and the second bridging region 38.

The portion of the source electrode 12 in contact with the body region 30, the anode region 34, and the second bridging region 38 is, for example, metal silicide. The metal silicide is, for example, titanium silicide or nickel silicide. For example, metal silicide is not provided in a portion of the source electrode 12 in contact with the second portion 28b of the drift region 28.

The junction between the anode region 34 and the second bridging region 38, and the source electrode 12 is, for example, an ohmic junction. The junction between the second portion 28b of the drift region 28 and the source electrode 12 is, for example, a Schottky junction.

FIG. 10(a), 10(b), 11, 12, and 13 are views illustrating a boundary portion between the transistor region 101 and the diode region 102.

As illustrated in FIG. 10(b), 11, and 13, the silicon carbide layer 10 at the boundary portion between the transistor region 101 and the diode region 102 includes a third bridging region 40 of p-type (seventh silicon carbide region).

The third bridging region 40 of p-type is provided between the drift region 28 and the first face P1. The third bridging region 40 is repeatedly disposed in the second direction.

The third bridging region 40 connects the body regions 30 and the anode regions 34 adjacent in the first direction.

The third bridging region 40 divides the drift region 28 extending in the second direction on the first face. The third bridging region 40 connects adjacent body regions 30 and anode regions 34, which are spaced apart with the drift region 28 of n-type interposed therebetween, by a silicon carbide region of p-type.

The third bridging region 40 is in contact with, for example, the first bridging region 36 and the second bridging region 38. The first bridging region 36, the second bridging region 38, and the third bridging region 40 are continuous, for example, in the first direction.

A distance (dz in FIG. 11) in the second direction between two adjacent third bridging regions 40 is, for example, less than the width (w1 in FIG. 1(a)) of the transistor region 101 in the first direction. The distance dz in the second direction between two adjacent third bridging regions 40 is, for example, equal to or more than 10 μm and equal to or less than 200 μm.

A width (wz in FIG. 11) of the third bridging region 40 in the second direction is, for example, less than a second distance (d2 in FIG. 11) between two adjacent second portions 28b in the first direction. The second distance d2 in the first direction between two adjacent second portions 28b is, for example, equal to or more than 3 μm and equal to or less than 30 μm. The width wz of the third bridging region 40 in the second direction is, for example, equal to or more than 1 μm and equal to or less than 10 μm.

The third bridging region 40 contains, for example, aluminum (Al) as p-type impurities. A p-type impurity concentration in the third bridging region 40 is, for example, equal to or more than 1×10¹⁶ cm⁻³ and equal to or less than 1×10²¹ cm⁻³.

The p-type impurity concentration in the third bridging region 40 is, for example, substantially the same as the p-type impurity concentration in the body region 30 and the anode region 34. The p-type impurity concentration in the third bridging region 40 is, for example, substantially the same as the p-type impurity concentration in the first bridging region 36. The p-type impurity concentration in the third bridging region 40 is, for example, substantially the same as the p-type impurity concentration in the second bridging region 38. Note that the p-type impurity concentration in the third bridging region 40 is defined by the p-type impurity concentration at a position half the depth of the third bridging region 40.

The depth of the third bridging region 40 is, for example, equal to or more than 0.3 μm and equal to or less than 1.0 μm. The depth of the third bridging region 40 is, for example, substantially the same as the depth of the body region 30 and the anode region 34. The depth of the third bridging region 40 is, for example, substantially the same as the depth of the first bridging region 36. The depth of the third bridging region 40 is, for example, substantially the same as the depth of the second bridging region 38.

An electric potential of the third bridging region 40 is fixed to the electric potential of the source electrode 12.

Note that, although FIG. 11 illustrates a case where two third bridging regions 40 are disposed in the second direction, the number of third bridging regions 40 may be equal to or greater than three.

The source electrode 12 is provided on the first face P1 of the silicon carbide layer 10. The source electrode 12 is in contact with the first face P1.

The source electrode 12 is in contact with the third bridging region 40.

The portion of the source electrode 12 in contact with the third bridging region 40 is, for example, metal silicide. The metal silicide is, for example, titanium silicide or nickel silicide.

The junction between the third bridging region 40 and the source electrode 12 is, for example, an ohmic junction.

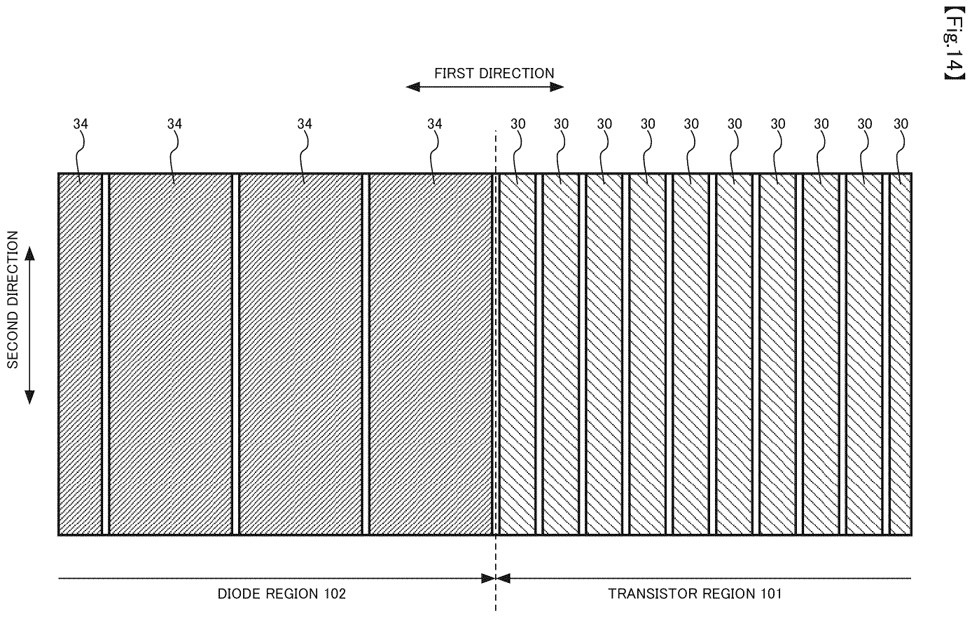

FIG. 14 is a schematic top view of the semiconductor device of the first embodiment. FIG. 14 is a view illustrating a pattern of the body region 30 projected onto the first face P1 and a pattern of the anode region 34 projected onto the first face P1. The pattern of the body region 30 and the pattern of the anode region 34 in FIG. 14 are patterns projected onto the first face P1 in a direction perpendicular to the first face P1.

Note that, in FIG. 14, a region where the first bridging region 36 intersects the body region 30 is also recognized as the body region 30. In addition, a region where the second bridging region 38 intersects with the anode region 34 is also regarded as the anode region 34.

An occupancy per unit area of the anode region 34 projected onto the first face P1 on the first face P1 is greater than an occupancy per unit area of the body region 30 projected onto the first face P1 on the first face P1.

In other words, in a region with a predetermined size, the occupancy of the anode region 34 projected onto the first face P1 on the first face P1 is greater than the occupancy of the body region 30 projected onto the first face P1 on the first face P1. That is, an occupancy ratio of the pn junction diode in the diode region 102 is greater than an occupancy ratio of the pn junction diode in the transistor region 101.

The occupancy per unit area of the anode region 34 projected onto the first face P1 is, for example, equal to or more than 1.2 times and equal to or less than 3 times the occupancy per unit area of the body region 30 projected onto the first face P1.

The unit area is not particularly limited as long as it is a size that allows comparison between an average occupancy of the body region 30 in the transistor region 101 and an average occupancy of the anode region 34 in the diode region 102. The unit area is, for example, 30 μm×30 μm=900 μm².

In addition, a contact area per unit area between the source electrode 12 and the anode region 34 in the diode region 102 is greater than a contact area per unit area between the source electrode 12 and the body region 30 in the transistor region 101. That is, a contact resistance per unit area between the source electrode 12 and the anode region 34 in the diode region 102 is lower than a contact resistance per unit area between the source electrode 12 and the body region 30 in the transistor region 101.

Next, a function and effect of the MOSFET 100 of the first embodiment will be described.

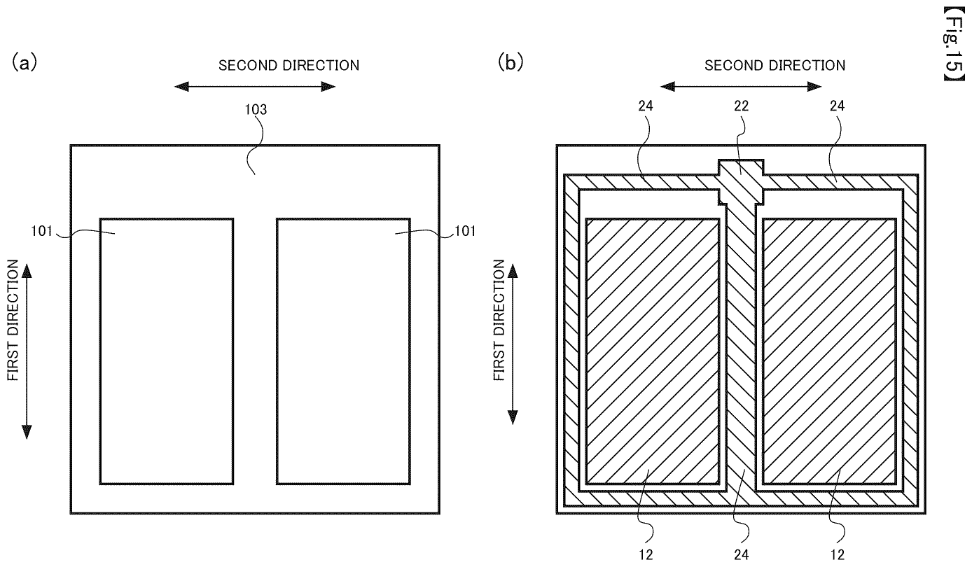

FIG. 15(a) and 15(b) are schematic top views of a semiconductor device of a first comparative example. FIG. 15(a) is an arrangement view of the respective regions included in a MOSFET of the first comparative example.

FIG. 15(b) is a view illustrating patterns of electrodes and wirings on an upper face of the MOSFET of the first comparative example. FIG. 15(a) and 15(b) are views corresponding to FIG. 1(a) and 1(b) of the first embodiment.

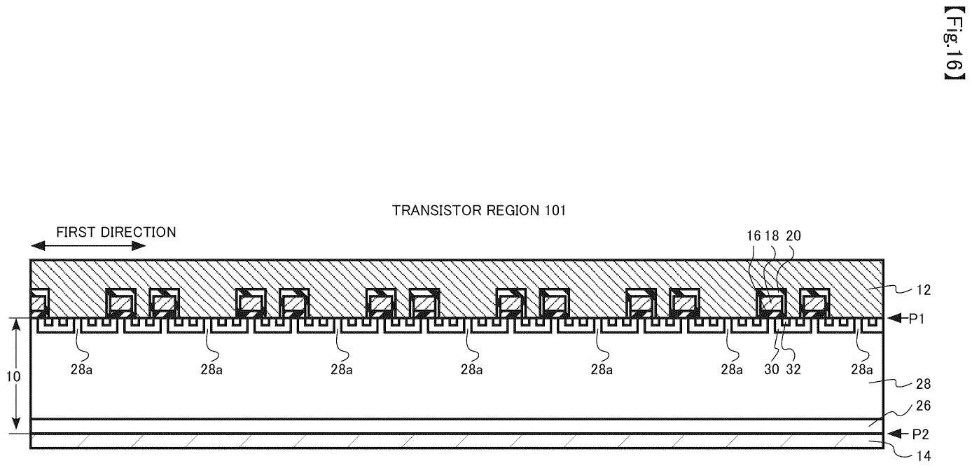

FIG. 16 is a schematic cross-sectional view of the semiconductor device of the first comparative example.

FIG. 16 is a cross-sectional view of the transistor region 101 of FIG. 15(a). FIG. 16 is a view corresponding to FIG. 2(a) of the first embodiment.

The MOSFET of the first comparative example differs from the MOSFET 100 of the first embodiment in that the diode region 102 is not provided.

In the transistor region 101 of the MOSFET of the first comparative example, a MOSFET and an SBD are provided similarly to the MOSFET 100 of the first embodiment.

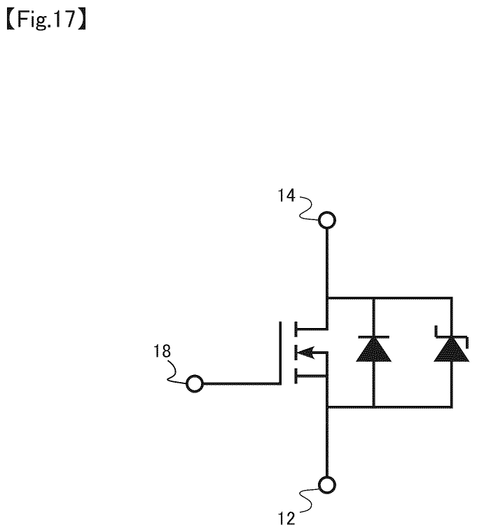

FIG. 17 is an equivalent circuit diagram of the semiconductor device of the first comparative example. A pn junction diode and an SBD are connected as built-in diodes in parallel with the transistor between the source electrode 12 and the drain electrode 14.

For example, a case where the MOSFET is used as a switching element connected to an inductive load is considered. When the MOSFET is off, a voltage that is positive with respect to the drain electrode 14 may be applied to the source electrode 12 due to a load current caused by the inductive load. In this case, a forward current flows through the built-in diode. This state is also referred to as a reverse conduction state.

A forward voltage (Vf) at which the forward current starts to flow through the SBD is lower than a forward voltage (Vf) of the pn junction diode. Therefore, first, the forward current flows through the SBD.

The forward voltage (Vf) of the SBD is, for example, 1.0 V. The forward voltage (Vf) of the pn junction diode is, for example, 2.5 V.

The SBD performs a unipolar operation. Therefore, even when the forward current flows, the stacking faults do not grow in the silicon carbide layer 10 due to the recombination energy of the carriers.

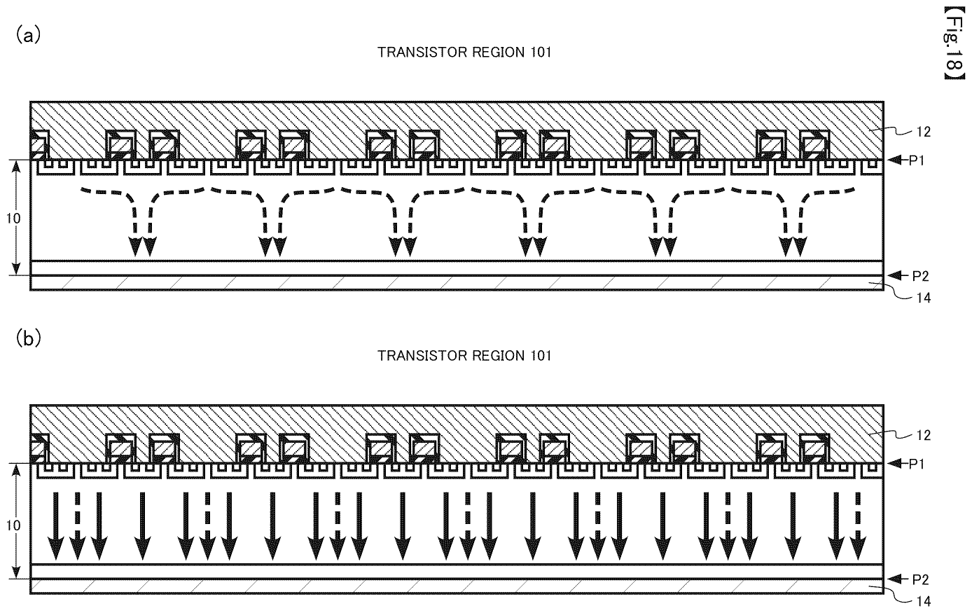

FIG. 18(a) and 18(b) are explanatory views of the function and effect of the semiconductor device of the first embodiment. FIG. 18(a) and 18(b) are schematic cross-sectional views of the first comparative example. FIG. 18(a) and 18(b) are views corresponding to FIG. 16.

FIG. 18(a) and 18(b) are views illustrating a current flowing through the built-in diode of the MOSFET of the first comparative example. FIG. 18(a) illustrates a state in which the forward current flows only through the SBD, and FIG. 18(b) illustrates a state in which the forward current flows through the SBD and the pn junction diode.

That is, FIG. 18(a) illustrates a state in which the voltage applied across the pn junction of the pn junction diode is lower than the forward voltage (Vf) of the pn junction diode. That is, FIG. 18(b) illustrates a state in which the voltage applied across the pn junction of the pn junction diode is higher than the forward voltage (Vf) of the pn junction diode.

In FIG. 18(a) and 18(b), the dotted arrow indicates the current flowing through the SBD. In FIG. 18(b), the solid arrow indicates a current flowing through the pn junction diode.

As illustrated in FIG. 18(a), the current flowing through the SBD flows around the bottom portion of the body region 30. Therefore, the electrostatic potential wraps around in the drift region 28 facing the bottom portion of the body region 30. The wraparound of the electrostatic potential reduces the voltage applied between the body region 30 and the drift region 28.

Therefore, at the bottom of the body region 30, the voltage hardly exceeds the forward voltage (Vf) of the pn junction diode. In other words, the forward voltage (Vf) of the pn junction diode of the MOSFET of the first comparative example can be made higher than a case where the SBD is not provided. Accordingly, bipolar operation of the pn junction diode is suppressed, and formation of stacking faults in the silicon carbide layer 10 due to carrier recombination energy is also suppressed.

The forward voltage (Vf) of the pn junction diode of the MOSFET of the first comparative example depends on the interval between two SBDs adjacent in the first direction. By reducing the interval between the two SBDs adjacent in the first direction, the forward voltage (Vf) of the pn junction diode of the MOSFET of the first comparative example can be increased.

A large surge current may be instantaneously applied to the MOSFET beyond the steady state. The surge current flows from the source electrode 12 toward the drain electrode 14.

When a large surge current flows, a large surge voltage is applied, heat is generated, and the MOSFET is destroyed. The maximum allowable peak current value (I_{FSM}) of the surge current tolerated by the MOSFET is referred to as surge current tolerance. In the MOSFET provided with an SBD, it is desirable to improve the surge current tolerance.

When a large surge voltage is applied to the MOSFET of the first comparative example, the voltage applied across the pn junction of the pn junction diode becomes greater than the forward voltage (Vf) of the pn junction diode.

When the voltage applied across the pn junction of the pn junction diode becomes greater than the forward voltage (Vf) of the pn junction diode, a current also flows through the pn junction diode as illustrated in FIG. 18(b).

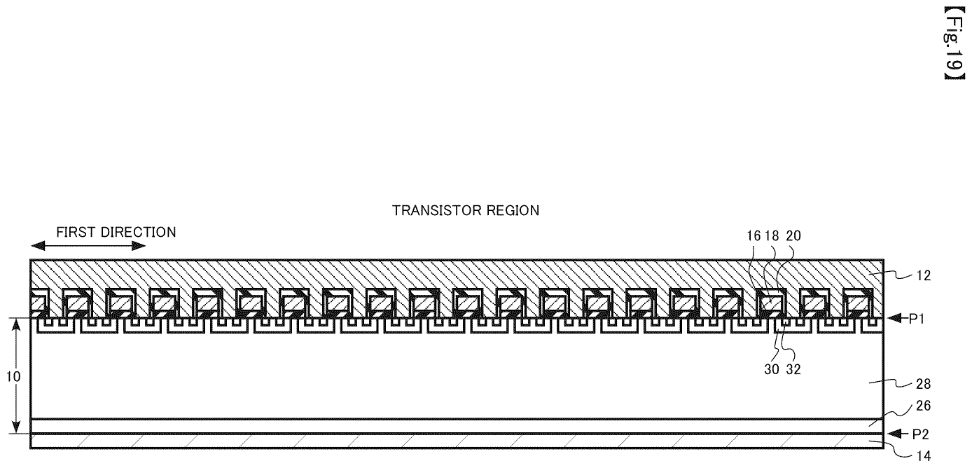

FIG. 19 is an explanatory view of the function and effect of the semiconductor device of the first embodiment. FIG. 19 is a schematic cross-sectional view of a second comparative example. FIG. 19 is a view corresponding to FIG. 16 of the first comparative example.

The MOSFET of the second comparative example differs from the MOSFET of the first comparative example in that the transistor region does not include the SBD. The built-in diode of the MOSFET of the second comparative example is only a pn junction diode.

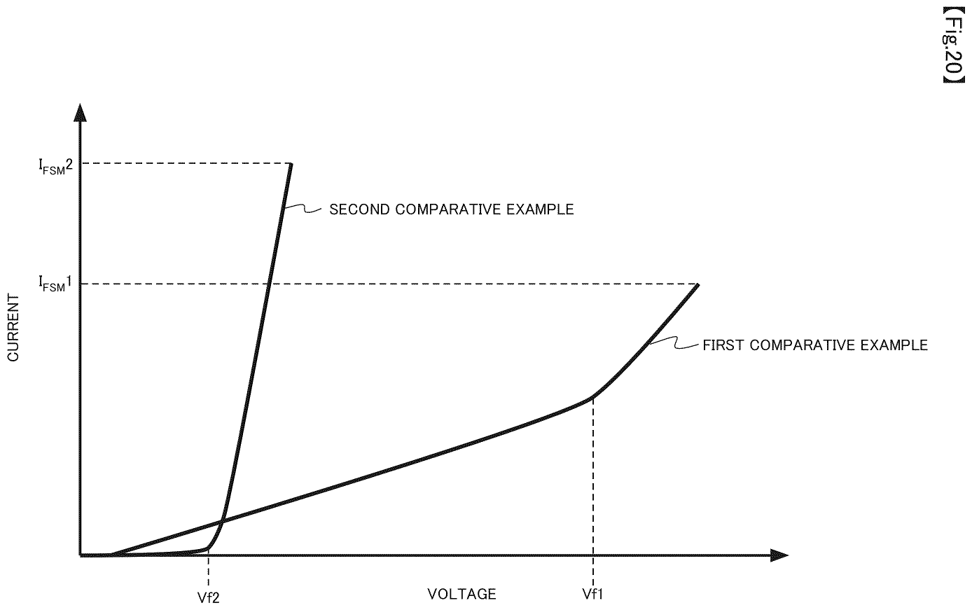

FIG. 20 is an explanatory view of the function and effect of the semiconductor device of the first embodiment. FIG. 20 is a view illustrating voltage-current characteristics of built-in diodes of the MOSFET of the first comparative example and the MOSFET of the second comparative example.

As illustrated in FIG. 20, in the MOSFET of the second comparative example, when a voltage equal to or higher than a forward voltage Vf2 of the pn junction diode is applied, a current flows through the pn junction diode. On the other hand, in the MOSFET of the first comparative example, a current flows through the SBD until a forward voltage Vf1 of the pn junction diode is applied. In the MOSFET of the first comparative example, when a voltage equal to or higher than the forward voltage Vf1 of the pn junction diode is applied, a current flows through the pn junction diode.

Since the MOSFET of the first comparative example operates in a unipolar manner up to the forward voltage Vf1, a slope of the current increase becomes lower than that of the MOSFET of the second comparative example.

Accordingly, the maximum allowable peak current value I_{FSM}1 of the MOSFET of the first comparative example becomes lower than the maximum allowable peak current value I_{FSM}2 of the MOSFET of the second comparative example. In other words, the surge current tolerance of the MOSFET of the first comparative example becomes lower than the surge current tolerance of the MOSFET of the second comparative example.

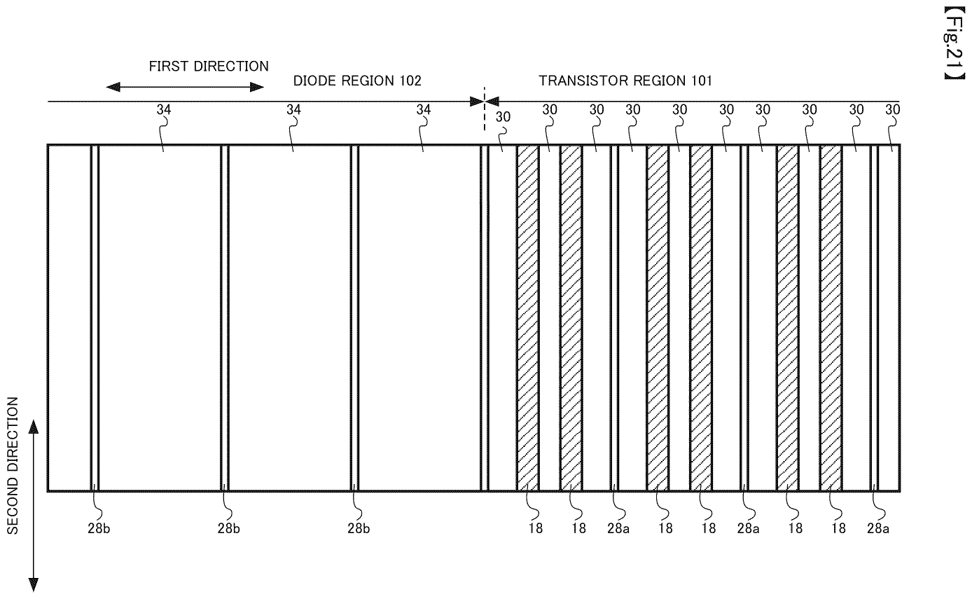

FIG. 21 is a schematic top view of a semiconductor device of a third comparative example. FIG. 21 is a view corresponding to FIG. 11 of the first embodiment.

A MOSFET of the third comparative example differs from the MOSFET 100 of the first embodiment in that the silicon carbide layer 10 does not include the first bridging region 36 of p-type (fourth silicon carbide region), the second bridging region 38 of p-type (sixth silicon carbide region), and the third bridging region 40 of p-type (seventh silicon carbide region).

The MOSFET of the third comparative example includes diode regions 102 alternately disposed with transistor regions 101, similarly to the MOSFET 100 of the first embodiment. Since the MOSFET of the third comparative example includes the diode regions 102, the surge current tolerance is improved. Details will be described below.

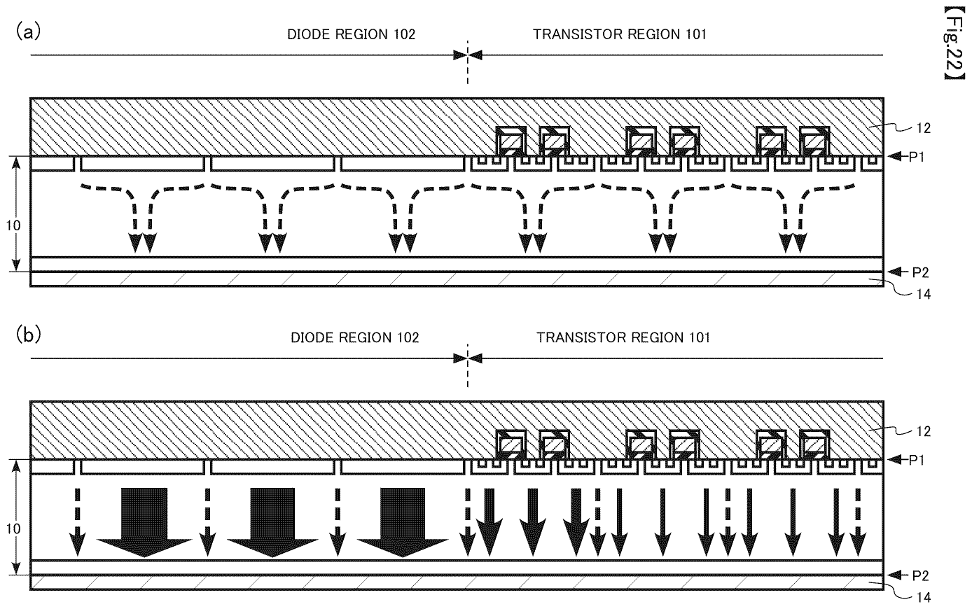

FIG. 22(a) and 22(b) are explanatory views of the function and effect of the semiconductor device of the first embodiment. FIG. 22(a) and 22(b) are schematic cross-sectional views of the MOSFET of the third comparative example. FIG. 22(a) and 22(b) are views corresponding to FIG. 10(a) of the first embodiment. The MOSFET of the third comparative example has the same structure as the structure illustrated in FIG. 10(a) of the first embodiment.

FIG. 22(a) and 22(b) are views illustrating a current flowing through the built-in diode of the MOSFET of the third comparative example. FIG. 22(a) illustrates a state in which the forward current flows only through the SBD, and FIG. 22(b) illustrates a state in which the forward current flows through the SBD and the pn junction diode.

That is, FIG. 22(a) illustrates a state in which the voltage applied across the pn junction of the pn junction diode is lower than the forward voltage (Vf) of the pn junction diode. That is, FIG. 22(b) illustrates a state in which the voltage applied across the pn junction of the pn junction diode is higher than the forward voltage (Vf) of the pn junction diode.

In FIG. 22(a) and 22(b), the dotted arrow indicates the current flowing through the SBD. In FIG. 22(b), the solid arrow indicates a current flowing through the pn junction diode.

In the diode region 102, a second distance d2 in the first direction between two adjacent second portions 28b with the anode region 34 interposed therebetween is substantially equal to a first distance d1 in the first direction between two adjacent first portions 28a with the body region 30 interposed therebetween in the transistor region 101. In other words, the diode region 102 is provided with the second portions 28b at the same interval as the first portions 28a in the transistor region 101. In other words, in the diode region 102, SBD regions are provided at the same interval as in the transistor region 101.

Therefore, as illustrated in FIG. 22(a), in the diode region 102, the current flowing through the SBD wraps around to the bottom of the anode region 34. Therefore, at the bottom of the anode region 34, it becomes difficult for the forward voltage (Vf) of the pn junction diode to be exceeded. The forward voltage (Vf) of the pn junction diode in the diode region 102 increases due to the provision of the SBD regions.

When the voltage applied across the pn junction of the pn junction diode becomes greater than the forward voltage (Vf) of the pn junction diode, a current also flows through the pn junction diode as illustrated in FIG. 22(b).

In the MOSFET of the third comparative example, for example, an occupancy per unit area of the anode region 34 projected onto the first face P1 is greater than an occupancy per unit area of the body region 30 projected onto the first face P1. That is, an occupancy ratio of the pn junction diode in the diode region 102 is greater than an occupancy ratio of the pn junction diode in the transistor region 101.

In addition, for example, a contact area per unit area between the source electrode 12 and the anode region 34 in the diode region 102 is greater than a contact area per unit area between the source electrode 12 and the body region 30 in the transistor region 101. That is, a contact resistance per unit area between the source electrode 12 and the anode region 34 in the diode region 102 is lower than a contact resistance per unit area between the source electrode 12 and the body region 30 in the transistor region 101.

Therefore, the current flowing through the pn junction diode of the diode region 102 becomes greater than the current flowing through the pn junction diode in the transistor region 101.

In addition, when a large current flows through the pn junction diode in the diode region 102, carrier propagation and heat propagation to the adjacent transistor region 101 occur. Therefore, conductivity modulation of the transistor region 101 adjacent to the diode region 102 is promoted. Therefore, the current flowing through the pn junction diode of the transistor region 101 adjacent to the diode region 102 increases.

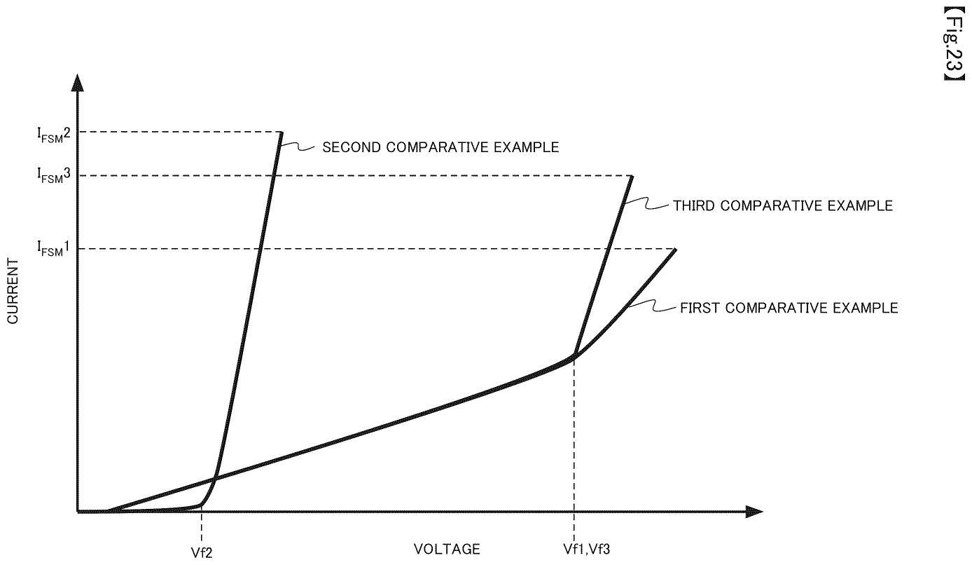

FIG. 23 is an explanatory view of the function and effect of the semiconductor device of the first embodiment. FIG. 23 is a view illustrating the voltage-current characteristics of the built-in diodes of the MOSFET of the first comparative example, the MOSFET of the second comparative example, and the MOSFET of the third comparative example.

As illustrated in FIG. 23, in the MOSFET of the third comparative example, a current flows through the SBD until the forward voltage Vf3 of the pn junction diode is applied. In the MOSFET of the third comparative example, when a voltage equal to or higher than the forward voltage Vf3 of the pn junction diode is applied, a current flows through the pn junction diode.

In the diode region 102 of the MOSFET of the third comparative example, SBD regions are provided at the same interval as in the transistor region 101. Accordingly, the forward voltage Vf3 of the pn junction diode of the MOSFET of the third comparative example is equal to the forward voltage Vf1 of the pn junction diode of the MOSFET of the first comparative example.

On the other hand, in the MOSFET of the third comparative example, the current after exceeding the forward voltage Vf3 of the pn junction diode becomes greater than the current after exceeding the forward voltage Vf1 of the pn junction diode in the MOSFET of the first comparative example. This is because the current flowing through the pn junction diode in the diode region 102 and the current flowing through the pn junction diode in the transistor region 101 adjacent to the diode region 102 become greater than those in the MOSFET of the first comparative example.

As the current after exceeding the forward voltage Vf3 of the pn junction diode increases, the maximum allowable peak current value I_{FSM}3 of the MOSFET of the third comparative example becomes greater than the maximum allowable peak current value I_{FSM}1 of the MOSFET of the first comparative example. In other words, the surge current tolerance of the MOSFET of the third comparative example becomes greater than the surge current tolerance of the MOSFET of the first comparative example.

As described above, the MOSFET of the third comparative example includes the diode region 102 provided between the transistor regions 101, thereby improving the surge current tolerance.

In the MOSFET 100 of the first embodiment, the silicon carbide layer 10 includes the first bridging region 36 of p-type (fourth silicon carbide region), the second bridging region 38 of p-type (sixth silicon carbide region), and the third bridging region 40 of p-type (seventh silicon carbide region), thereby further improving the surge current tolerance compared to the MOSFET of the third comparative example. Details will be described below.

For example, in the MOSFET of the third comparative example, the surge current flowing through the MOSFET may vary within the chip. The variation of the surge current within the chip is considered to be due to variations in the start of the operation of the pn junction diodes provided in the diode region 102 and the transistor region 101, as well as variations in the rise of the forward current after the start of the operation.

When the surge current varies within the chip, the amount of heat generation may become locally large, for example. Therefore, the MOSFET may be locally destroyed, resulting in a decrease in surge current tolerance.

In the MOSFET 100 of the first embodiment, by including the first bridging region 36 of p-type (fourth silicon carbide region), the second bridging region 38 of p-type (sixth silicon carbide region), and the third bridging region 40 of p-type (seventh silicon carbide region), a plurality of body regions 30 of p-type and a plurality of anode regions 34 of p-type extending in the second direction are connected in the first direction via p-type regions. The first bridging region 36, the second bridging region 38, and the third bridging region 40 that connect the body regions 30 and the anode regions 34 promote the movement of the holes in the first direction, such that the start of the operation of the pn junction diodes provided in the diode region 102 and the transistor region 101 and the rise of the forward current after the start of the operation can be made uniform in the chip.

According to the MOSFET 100 of the first embodiment, it is possible to suppress variation in surge current flowing through the MOSFET in the chip. Therefore, according to the MOSFET 100 of the first embodiment, the surge current tolerance is improved.

It is preferable that a distance (dx in FIG. 3) between two adjacent first bridging regions 36 in the second direction is less than a width (w1 in FIG. 1(a)) of the transistor region 101 in the first direction. Since the distance dx in the second direction is less than the width w1 of the transistor region 101 in the first direction, it is possible to further uniformize, within the chip, the start of operation of the pn junction diodes provided in the transistor region 101 and the rise of the forward current after the operation starts.

It is preferable that a width (wx in FIG. 3) of the first bridging region 36 in the second direction is less than a first distance (d1 in FIG. 2(a) and 3) between two adjacent first portions 28a in the first direction. By setting the width wx of the first bridging region 36 in the second direction to be less than the first distance d1 in the first direction between two adjacent first portions 28a, a decrease in the forward voltage (Vf) of the pn junction diode in the transistor region 101 can be suppressed.

It is preferable that a width (wy in FIG. 7) of the second bridging region 38 in the second direction is, for example, less than a width (wb in FIG. 7) of the anode region 34 in the first direction. By setting the width (wy in FIG. 7) of the second bridging region 38 in the second direction to be less than, for example, the width (wb in FIG. 7) of the anode region 34 in the first direction, a decrease in the forward voltage (Vf) of the pn junction diode in the diode region 102 can be suppressed.

From the viewpoint of suppressing a decrease in the forward voltage (Vf) of the pn junction diode in the diode region 102, it is preferable that the width (wy in FIG. 7) of the second bridging region 38 in the second direction is equal to or less than half the width (wb in FIG. 7) of the anode region 34 in the first direction. From the viewpoint of suppressing a decrease in the forward voltage (Vf) of the pn junction diode in the diode region 102, it is preferable that the width (wy in FIG. 7) of the second bridging region 38 in the second direction is equal to or less than 10 μm.

It is preferable that a width (wy in FIG. 7) of the second bridging region 38 in the second direction is less than a second distance (d2 in FIG. 6(a) and 7) between two adjacent second portions 28b in the first direction. By setting the width wy of the second bridging region 38 in the second direction to be less than the second distance d2 in the first direction between two adjacent second portions 28b, a decrease in the forward voltage (Vf) of the pn junction diode in the diode region 102 can be suppressed.

From the viewpoint of increasing the on-current of the MOSFET 100, it is preferable that the width (w1 in FIG. 1(a)) of the transistor region 101 in the first direction is greater than the width (w2 in FIG. 1(a)) of the diode region 102 in the first direction.

### First Modification

A semiconductor device of a first modification differs from the semiconductor device of the first embodiment in that a depth of the fourth silicon carbide region is greater than a depth of the second silicon carbide region, and a depth of the sixth silicon carbide region is greater than a depth of the fifth silicon carbide region.

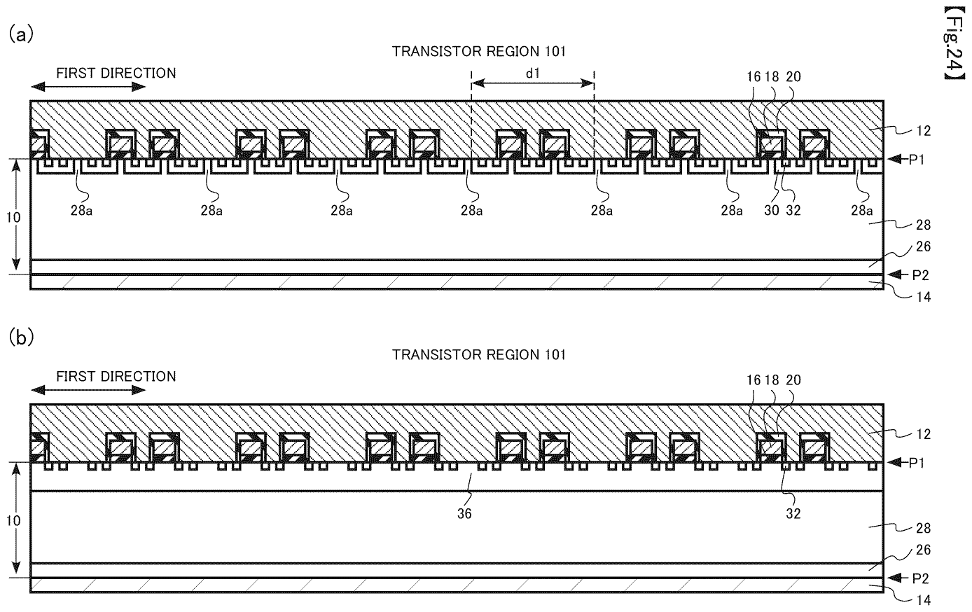

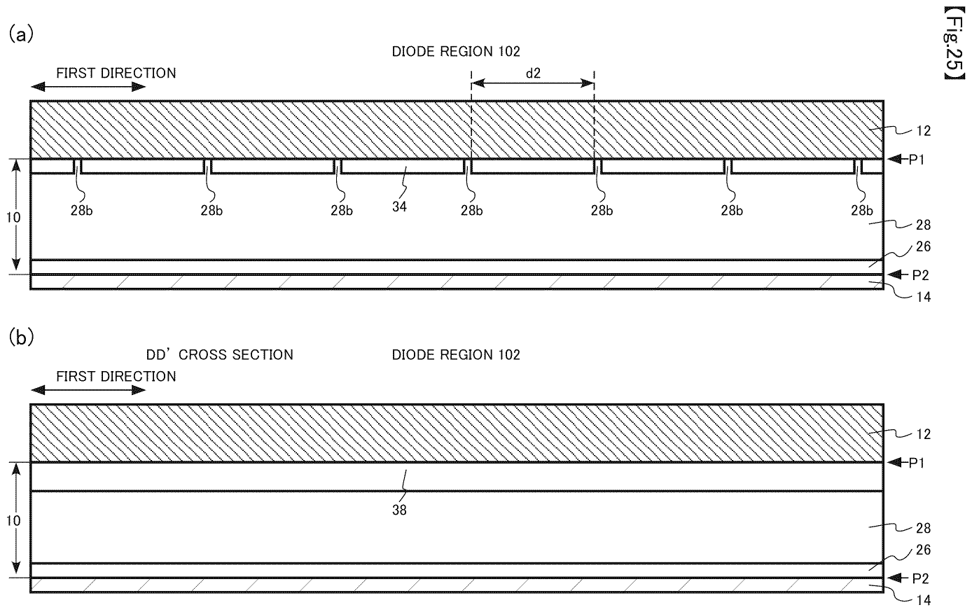

FIG. 24(a), 24(b), 25(a), and 25(b) are schematic cross-sectional views of the semiconductor device according to the first modification of the first embodiment. FIG. 24(a) and 24(b) are views corresponding to FIG. 2(a) and 2(b) of the first embodiment. In addition, FIG. 25(a) and 25(b) are views corresponding to FIG. 6(a) and 6(b) of the first embodiment.

As illustrated in FIG. 24(a) and 24(b), in the MOSFET of the first modification, a depth of the first bridging region 36 of p-type (fourth silicon carbide region) is greater than a depth of the body region 30 of p-type (second silicon carbide region). In addition, as illustrated in FIG. 25(a) and 25(b), a depth of the second bridging region 38 of p-type (sixth silicon carbide region) is greater than a depth of the anode region 34 of p-type (fifth silicon carbide region).

The depths of the first bridging region 36 of p-type and the second bridging region 38 of p-type further promote the movement of the holes in the first direction.

Therefore, according to the MOSFET of the first modification, the surge current tolerance is further improved.

### Second Modification

A semiconductor device of a second modification differs from the semiconductor device of the first embodiment in that the p-type impurity concentration in the fourth silicon carbide region is higher than the p-type impurity concentration in the second silicon carbide region, and the p-type impurity concentration in the sixth silicon carbide region is higher than the p-type impurity concentration in the fifth silicon carbide region.

In the MOSFET of the second modification, the p-type impurity concentration in the first bridging region 36 of p-type (fourth silicon carbide region) is higher than the p-type impurity concentration of the body region 30 of p-type (second silicon carbide region). In addition, the p-type impurity concentration in the second bridging region 38 of p-type (sixth silicon carbide region) is higher than the p-type impurity concentration in the anode region 34 of p-type (fifth silicon carbide region).

Because the p-type impurity concentrations in the first bridging region 36 of p-type and the second bridging region 38 of p-type are high, the movement of holes in the first direction is further promoted. Therefore, according to the MOSFET of the second modification, the surge current tolerance is further improved.

As described above, according to the first embodiment and the modifications, it is possible to provide a semiconductor device with improved surge current tolerance.

### Second Embodiment

A semiconductor device of a second embodiment differs from the semiconductor device of the first embodiment in that the fourth silicon carbide region does not intersect the second silicon carbide region, and the sixth silicon carbide region does not intersect the fifth silicon carbide region. Hereinafter, some descriptions of contents overlapping with the first embodiment may be omitted.

Similarly to the semiconductor device of the first embodiment, the semiconductor device of the second embodiment is a vertical MOSFET 200 of a planar gate type using silicon carbide.

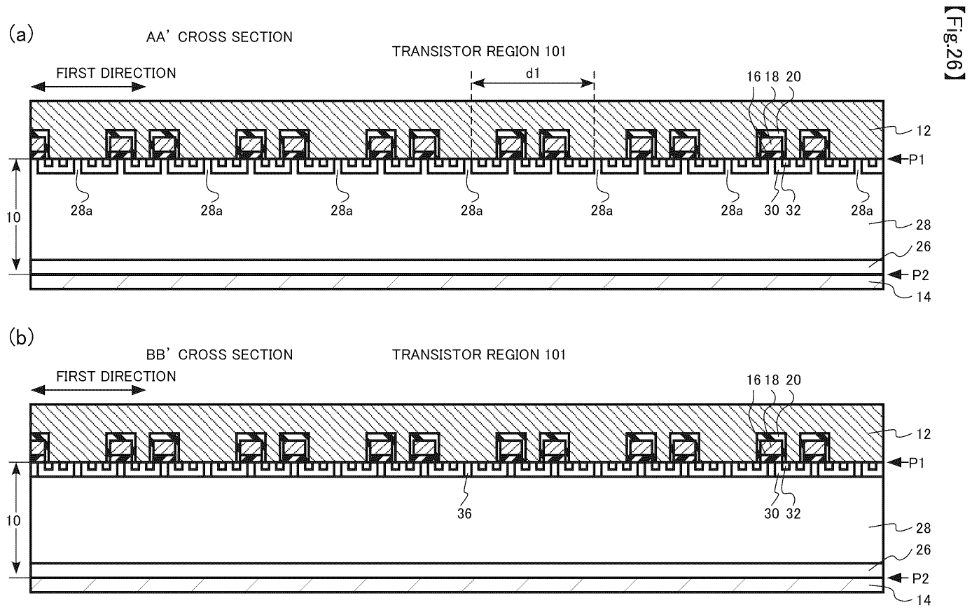

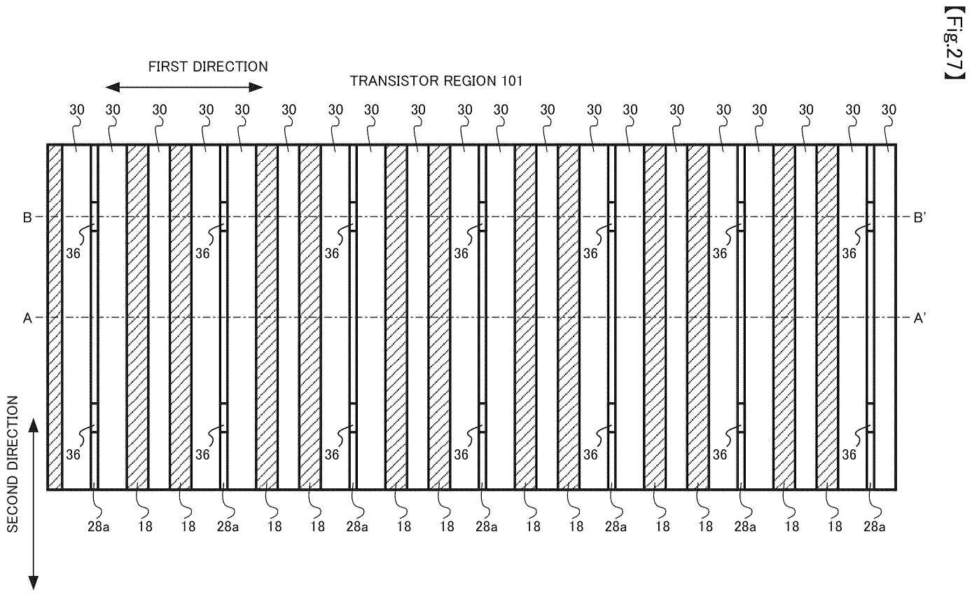

FIG. 26(a) and 26(b) are schematic cross-sectional views of a part of the semiconductor device of the second embodiment. FIG. 27 is a schematic top view of a part of the semiconductor device of the second embodiment. FIG. 26(a) is a cross section taken along line AA′ of FIG. 27. FIG. 26(b) is a cross section taken along line BB′ of FIG. 27.

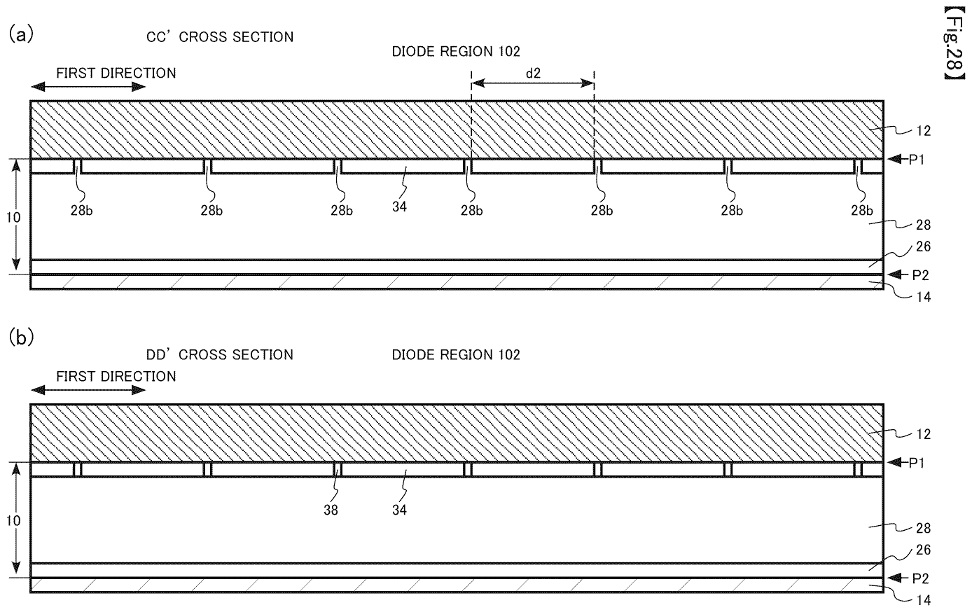

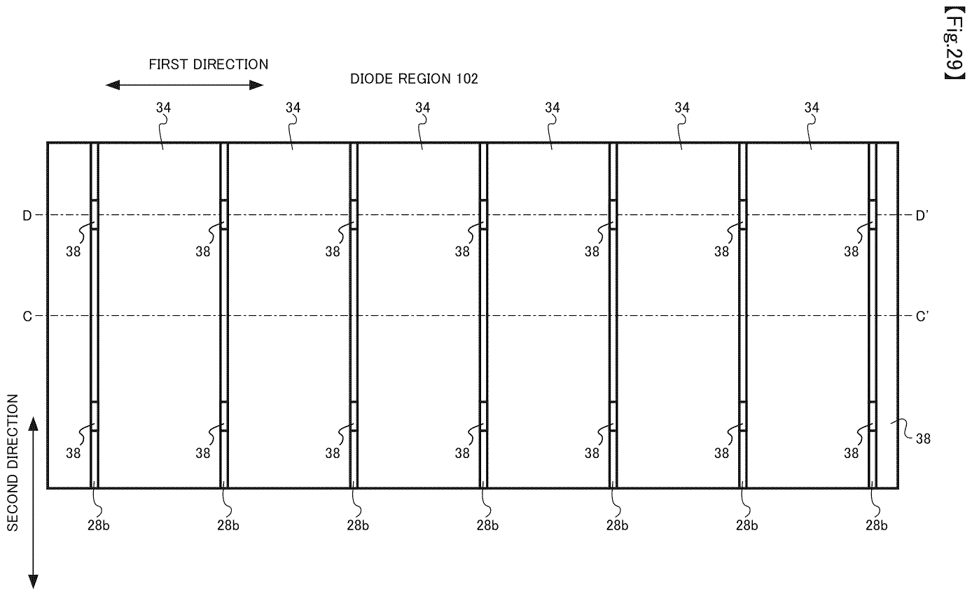

FIG. 28(a) and 28(b) are schematic cross-sectional views of a part of the semiconductor device of the second embodiment. FIG. 29 is a schematic top view of a part of the semiconductor device of the second embodiment. FIG. 28(a) is a cross section taken along line CC′ of FIG. 29. FIG. 28(b) is a cross section taken along line DD′ of FIG. 29.

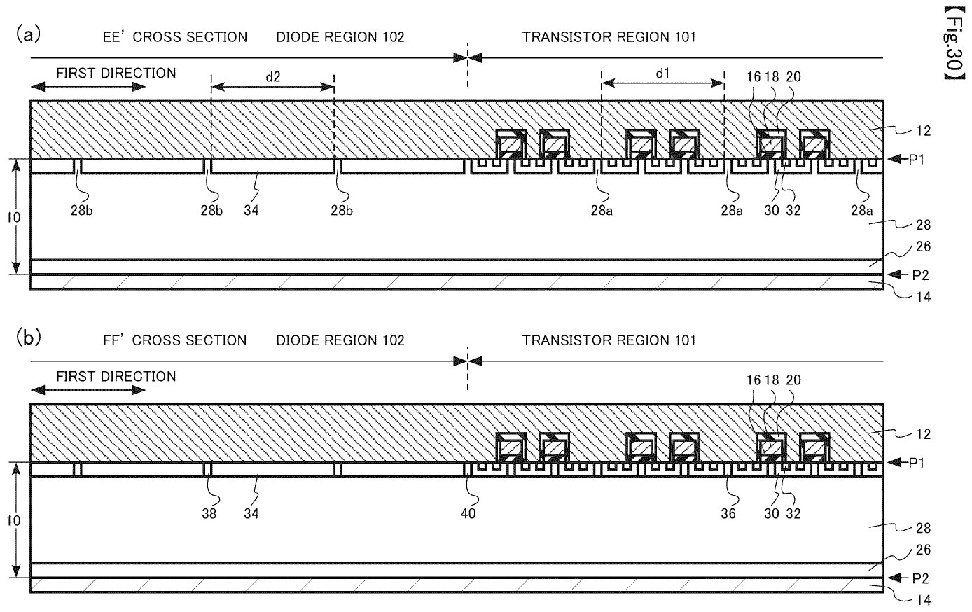

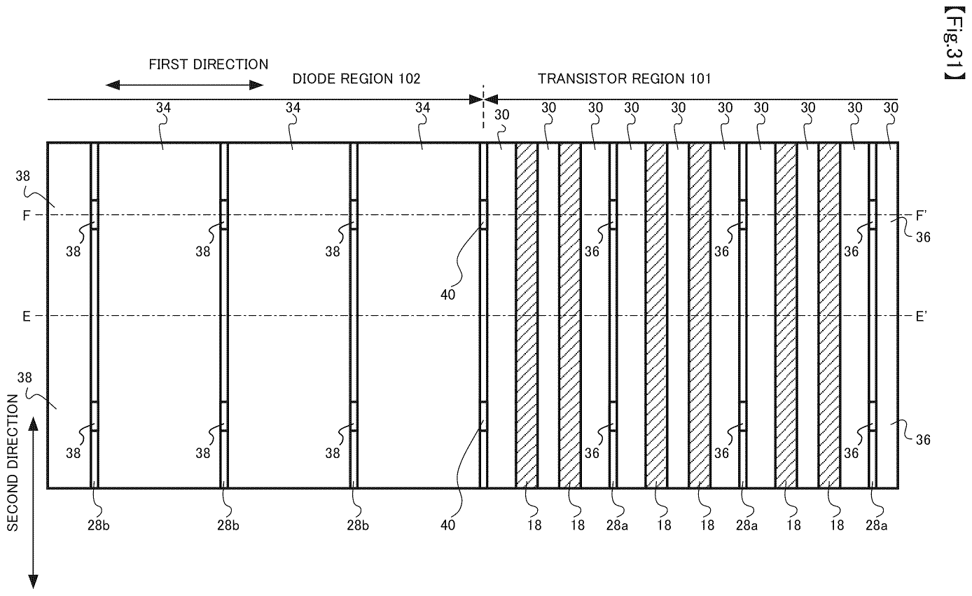

FIG. 30(a) and 30(b) are schematic cross-sectional views of a part of the semiconductor device of the second embodiment. FIG. 31 is a schematic top view of a part of the semiconductor device of the second embodiment. FIG. 30(a) is a cross section taken along line EE′ of FIG. 31. FIG. 30(b) is a cross section taken along line FF′ of FIG. 31.

The MOSFET 200 includes a silicon carbide layer 10, a source electrode 12 (first electrode), a drain electrode 14 (second electrode), a gate insulating layer 16, a gate electrode 18, an interlayer insulating layer 20, a gate electrode pad 22, and a gate wiring 24.

The silicon carbide layer 10 includes a drain region 26 of n⁺-type, a drift region 28 of n⁻-type (first silicon carbide region), a body region 30 of p-type (second silicon carbide region), a source region 32 of n⁺-type (third silicon carbide region), an anode region 34 of p-type (fifth silicon carbide region), a first bridging region 36 of p-type (fourth silicon carbide region), a second bridging region 38 of p-type (sixth silicon carbide region), and a third bridging region 40 of p-type (seventh silicon carbide region).

The drift region 28 has a plurality of first portions 28a and a plurality of second portions 28b.

FIG. 26(a), 26(b), and 27 are views illustrating the transistor region 101.

As illustrated in FIG. 26(a), 26(b), 27, the transistor region 101 includes a silicon carbide layer 10, a source electrode 12 (first electrode), a drain electrode 14 (second electrode), a gate insulating layer 16, a gate electrode 18, and an interlayer insulating layer 20. The silicon carbide layer 10 of the transistor region 101 includes a drain region 26 of n⁺-type, a drift region 28 of n⁻-type (first silicon carbide region), a plurality of body regions 30 of p-type (second silicon carbide region), a plurality of source regions 32 of n⁺-type (third silicon carbide region), and a plurality of first bridging regions 36 of p-type (fourth silicon carbide region).

Note that FIG. 27 illustrates only patterns of the drift region 28, the body region 30, the first bridging region 36, and the gate electrode 18.

The first bridging region 36 of p-type is provided between the drift region 28 and the first face P1. The first bridging region 36 is repeatedly disposed in the second direction.

The first bridging region 36 connects two body regions 30 adjacent in the first direction. The first bridging region 36 is repeatedly disposed, for example, in the first direction. Two first bridging regions 36 adjacent in the first direction sandwich the body region 30 therebetween.

The first bridging region 36 divides the first portion 28a extending in the second direction. The first bridging region 36 connects two adjacent body regions 30 spaced apart with the first portion 28a of n-type interposed therebetween by a silicon carbide region of p-type.

A distance in the second direction between two adjacent first bridging regions 36 is, for example, less than the width of the transistor region 101 in the first direction. The distance in the second direction between two adjacent first bridging regions 36 is, for example, equal to or more than 10 μm and equal to or less than 200 μm.

A width of the first bridging region 36 in the second direction is, for example, less than the distance between two adjacent first portions 28a. The distance between two adjacent first portions 28a is, for example, equal to or more than 3 μm and equal to or less than 30 μm. The width of the first bridging region 36 in the second direction is, for example, equal to or more than 1 μm and equal to or less than 10 μm.

The first bridging region 36 contains, for example, aluminum (Al) as p-type impurities. A p-type impurity concentration in the first bridging region 36 is, for example, equal to or more than 1×10¹⁶ cm⁻³ and equal to or less than 1×10²¹ cm⁻³. The p-type impurity concentration in the first bridging region 36 is, for example, substantially the same as the p-type impurity concentration in the body region 30.

The depth of the first bridging region 36 is, for example, equal to or more than 0.3 μm and equal to or less than 1.0 μm. The depth of the first bridging region 36 is, for example, substantially the same as the depth of the body region 30.

Note that, although FIG. 27 illustrates a case where two first bridging regions 36 are disposed in the second direction, the number of first bridging regions 36 may be equal to or greater than three.

FIG. 28(a), 28(b), and 29 are views illustrating the diode region 102.

As illustrated in FIG. 28(a), 28(b), and 29, the diode region 102 includes the silicon carbide layer 10, the source electrode 12 (first electrode), and the drain electrode 14 second electrode). The silicon carbide layer 10 of the diode region 102 includes a drain region 26 of n⁺-type, a drift region 28 of n⁻-type (first silicon carbide region), a plurality of anode regions 34 of p-type (fifth silicon carbide region), and a second bridging region 38 of p-type (sixth silicon carbide region).

Note that FIG. 29 illustrates only patterns of the drift region 28, the anode region 34, and the second bridging region 38.

The drift region 28 has a plurality of second portions 28b. The second portions 28b are in contact with the first face P1.

The second bridging region 38 of p-type is provided between the drift region 28 and the first face P1. The second bridging region 38 is repeatedly disposed in the second direction.

The second bridging region 38 connects two anode regions 34 adjacent in the first direction. The second bridging region 38 is repeatedly disposed in the first direction. Two second bridging regions 38 adjacent in the first direction sandwich the anode region 34 therebetween.

The second bridging region 38 divides the second portion 28b extending in the second direction. The second bridging region 38 connects two adjacent anode regions 34 spaced apart with the second portion 28b of n-type interposed therebetween by a silicon carbide region of p-type.

A distance in the second direction between two adjacent second bridging regions 38 is, for example, less than the width of the transistor region 101 in the first direction. The distance in the second direction between two adjacent second bridging regions 38 is, for example, equal to or more than 10 μm and equal to or less than 200 μm.

A width of the second bridging region 38 in the second direction is, for example, less than the distance between two adjacent second portions 28b. The distance between two adjacent second portions 28b is, for example, equal to or more than 3 μm and equal to or less than 30 μm. The width of the second bridging region 38 in the second direction is, for example, equal to or more than 1 μm and equal to or less than 10 μm.

The distance between two adjacent second portions 28b is, for example, substantially equal to the distance between two adjacent first portions 28a.

The second bridging region 38 contains, for example, aluminum (Al) as p-type impurities. A p-type impurity concentration in the second bridging region 38 is, for example, equal to or more than 1×10¹⁶ cm⁻³ and equal to or less than 1×10²¹ cm⁻³. The p-type impurity concentration in the second bridging region 38 is, for example, substantially the same as the p-type impurity concentration in the anode region 34. The p-type impurity concentration in the second bridging region 38 is, for example, substantially the same as the p-type impurity concentration in the first bridging region 36.

The depth of the second bridging region 38 is, for example, equal to or more than 0.3 μm and equal to or less than 1.0 μm. The depth of the second bridging region 38 is, for example, substantially the same as the depth of the anode region 34. The depth of the second bridging region 38 is, for example, substantially the same as the depth of the first bridging region 36.

Note that, although FIG. 29 illustrates a case where two second bridging regions 38 are disposed in the second direction, the number of second bridging regions 38 may be equal to or greater than three.

FIG. 30(a), 30(b), and 31 are views illustrating a boundary portion between the transistor region 101 and the diode region 102.

As illustrated in FIG. 30(b) and 31, the silicon carbide layer 10 at the boundary portion between the transistor region 101 and the diode region 102 includes a third bridging region 40 of p-type (seventh silicon carbide region).

The third bridging region 40 of p-type is provided between the drift region 28 and the first face P1. The third bridging region 40 is repeatedly disposed in the second direction.

The third bridging region 40 connects the body regions 30 and the anode regions 34 adjacent in the first direction.

The third bridging region 40 divides the drift region 28 extending in the second direction on the first face. The third bridging region 40 connects adjacent body regions 30 and anode regions 34, which are spaced apart with the drift region 28 of n-type interposed therebetween, by a silicon carbide region of p-type.

The first bridging region 36, the second bridging region 38, and the third bridging region 40 are, for example, disposed side by side in the first direction.

A distance in the second direction between two adjacent third bridging regions 40 is, for example, less than the width of the transistor region 101 in the first direction. The distance in the second direction between two adjacent third bridging regions 40 is, for example, equal to or more than 10 μm and equal to or less than 200 μm.

A width of the third bridging region 40 in the second direction is, for example, less than the distance between two adjacent second portions 28b. The distance between two adjacent second portions 28b is, for example, equal to or more than 3 μm and equal to or less than 30 μm. The width of the third bridging region 40 in the second direction is, for example, equal to or more than 1 μm and equal to or less than 10 μm.

The third bridging region 40 contains, for example, aluminum (Al) as p-type impurities. A p-type impurity concentration in the third bridging region 40 is, for example, equal to or more than 1×10¹⁶ cm⁻³ and equal to or less than 1×10²¹ cm⁻³. The p-type impurity concentration in the third bridging region 40 is, for example, substantially the same as the p-type impurity concentration in the body region 30 and the anode region 34. The p-type impurity concentration in the third bridging region 40 is, for example, substantially the same as the p-type impurity concentration in the first bridging region 36. The p-type impurity concentration in the third bridging region 40 is, for example, substantially the same as the p-type impurity concentration in the second bridging region 38.

The depth of the third bridging region 40 is, for example, equal to or more than 0.3 μm and equal to or less than 1.0 μm. The depth of the third bridging region 40 is, for example, substantially the same as the depth of the body region 30 and the anode region 34. The depth of the third bridging region 40 is, for example, substantially the same as the depth of the first bridging region 36. The depth of the third bridging region 40 is, for example, substantially the same as the depth of the second bridging region 38.

Note that, although FIG. 31 illustrates a case where two third bridging regions 40 are disposed in the second direction, the number of third bridging regions 40 may be equal to or greater than three.

An occupancy per unit area of the anode region 34 projected onto the first face P1 on the first face P1 is greater than an occupancy per unit area of the body region 30 projected onto the first face P1 on the first face P1.

In other words, in a region with a predetermined size, the occupancy of the anode region 34 projected onto the first face P1 on the first face P1 is greater than the occupancy of the body region 30 projected onto the first face P1 on the first face P1. That is, an occupancy ratio of the pn junction diode in the diode region 102 is greater than an occupancy ratio of the pn junction diode in the transistor region 101.

The occupancy per unit area of the anode region 34 projected onto the first face P1 is, for example, equal to or more than 1.2 times and equal to or less than 3 times the occupancy per unit area of the body region 30 projected onto the first face P1.

The unit area is not particularly limited as long as it is a size that allows comparison between an average occupancy of the body region 30 in the transistor region 101 and an average occupancy of the anode region 34 in the diode region 102. The unit area is, for example, 30 μm×30 μm=900 μm².

In addition, a contact area per unit area between the source electrode 12 and the anode region 34 in the diode region 102 is greater than a contact area per unit area between the source electrode 12 and the body region 30 in the transistor region 101. That is, a contact resistance per unit area between the source electrode 12 and the anode region 34 in the diode region 102 is lower than a contact resistance per unit area between the source electrode 12 and the body region 30 in the transistor region 101.

In the MOSFET 200 of the second embodiment, similarly to the MOSFET 100 according to the first embodiment, by including the first bridging region 36 of p-type (fourth silicon carbide region), the second bridging region 38 of p-type (sixth silicon carbide region), and the third bridging region 40 of p-type (seventh silicon carbide region), a body region 30 of p-type and an anode region 34 of p-type extending in the second direction are connected in the first direction via p-type regions. The first bridging region 36, the second bridging region 38, and the third bridging region 40 that connect the body regions 30 and the anode regions 34 promote the movement of the holes in the first direction, such that the start of the operation of the pn junction diodes provided in the diode region 102 and the transistor region 101 and the rise of the forward current after the start of the operation can be made uniform in the chip.

According to the MOSFET 200 of the second embodiment, it is possible to suppress variation in surge current flowing through the MOSFET in the chip. Therefore, according to the MOSFET 200 of the second embodiment, the surge current tolerance is improved.

Note that, in the MOSFET 200 of the second embodiment, a depth of the first bridging region 36 of p-type (fourth silicon carbide region) can be made greater than a depth of the body region 30 of p-type (second silicon carbide region). In addition, a depth of the second bridging region 38 of p-type (sixth silicon carbide region) can be made greater than a depth of the anode region 34 of p-type (fifth silicon carbide region).

In addition, in the MOSFET 200 of the second embodiment, a p-type impurity concentration in the first bridging region 36 of p-type (fourth silicon carbide region) can be made greater than a p-type impurity concentration of the body region 30 of p-type (second silicon carbide region). In addition, the p-type impurity concentration in the second bridging region 38 of p-type (sixth silicon carbide region) can be made higher than the p-type impurity concentration in the anode region 34 of p-type (fifth silicon carbide region).

In addition, in the MOSFET 200 of the second embodiment, the plurality of first bridging regions 36 may not necessarily be aligned along the first direction.

Similarly, the plurality of second bridging regions 38 may not necessarily be aligned along the first direction. In addition, the first bridging region 36, the second bridging region 38, and the third bridging region 40 may not necessarily be arranged side by side in the first direction.

As described above, according to the second embodiment, it is possible to provide a semiconductor device with improved surge current tolerance.

In the first and second embodiments, the case of 4H—SiC is described as an example of the crystal structure of SiC, but the present invention can also be applied to devices using SiC having other crystal structures such as 6H—SiC and 3C—SiC. In addition, it is also possible to apply a face other than the (0001) face to the surface of the silicon carbide layer 10.

In the first and second embodiments, aluminum (Al) is exemplified as the p-type impurities, but boron (B) can also be used. In addition, nitrogen (N) and phosphorus (P) are exemplified as the n-type impurities, but arsenic (As), antimony (Sb), and the like can also be applied.

Although some embodiments of the present invention have been described, these embodiments have been presented as examples and are not intended to limit the scope of the invention. These novel embodiments can be implemented in various other forms, and various omissions, substitutions, and modifications can be made without departing from the gist of the invention. For example, a component of one embodiment may be replaced with or modified by a component of another embodiment. These embodiments and modifications thereof are included in the scope and gist of the invention, and are included within the scope of the invention described in the claims and equivalents thereof.

### REFERENCE SIGNS LIST

10 Silicon carbide layer
12 Source electrode (first electrode)
14 Drain electrode (second electrode)
16 Gate insulating layer
18 Gate electrode
28 Drift region (first silicon carbide region)
28a First portion
28b Second portion
30 Body region (second silicon carbide region)
32 Source region (third silicon carbide region)
34 Anode region (fifth silicon carbide region)
36 First bridging region (fourth silicon carbide region)
38 Second bridging region (sixth silicon carbide region)
40 Third bridging region (seventh silicon carbide region)
100 MOSFET (semiconductor device)
101 Transistor region
102 Diode region
P1 First face
P2 Second face

1. A semiconductor device comprising a plurality of transistor regions and a plurality of diode regions alternately disposed in a first direction,
wherein the transistor region includes:
a silicon carbide layer having a first face and a second face facing the first face,
the silicon carbide layer including:
a first silicon carbide region of n-type having a plurality of first portions that are in contact with the first face, extend in a second direction orthogonal to the first direction, and are disposed in the first direction;
a plurality of second silicon carbide regions of p-type provided between the first silicon carbide region and the first face, extending in the second direction, and disposed in the first direction;
a third silicon carbide region of n-type provided between the second silicon carbide regions and the first face; and
a plurality of fourth silicon carbide regions of p-type provided between the first silicon carbide region and the first face, disposed in the second direction, and connecting two adjacent second silicon carbide regions;
a first electrode in contact with the first portions, the second silicon carbide regions, the third silicon carbide region, and the fourth silicon carbide regions;
a second electrode in contact with the second face;
a plurality of gate electrodes facing the second silicon carbide regions, extending in the second direction, and disposed in the first direction; and
a gate insulating layer provided between the gate electrodes and the second silicon carbide regions, the diode region includes:
the silicon carbide layer including:
the first silicon carbide region of n-type having a plurality of second portions in contact with the first face and extending in the second direction;
a plurality of fifth silicon carbide regions of p-type provided between the first silicon carbide region and the first face, extending in the second direction, and disposed in the first direction; and
a plurality of sixth silicon carbide regions of p-type provided between the first silicon carbide region and the first face, disposed in the second direction, and connecting two adjacent fifth silicon carbide regions;
the first electrode in contact with the second portions, the fifth silicon carbide regions, and the sixth silicon carbide regions; and
the second electrode, and
the silicon carbide layer further includes a plurality of seventh silicon carbide regions of p-type provided between the first silicon carbide region and the first face, disposed in the second direction, and connecting adjacent second silicon carbide regions and adjacent fifth silicon carbide regions.

2. The semiconductor device according to claim 1, wherein an occupancy per unit area of the fifth silicon carbide regions projected onto the first face is greater than an occupancy per unit area of the second silicon carbide regions projected onto the first face.

3. The semiconductor device according to claim 2, wherein a contact area per unit area between the first electrode and the fifth silicon carbide regions is greater than a contact area per unit area between the first electrode and the second silicon carbide regions.

4. The semiconductor device according to claim 1, wherein a width of the sixth silicon carbide regions in the second direction is less than a width of the fifth silicon carbide regions in the first direction.

5. The semiconductor device according to claim 1, wherein a distance in the second direction between two adjacent fourth silicon carbide regions is less than a width of the transistor region in the first direction.

6. The semiconductor device according to claim 1, wherein the fourth silicon carbide regions extend in the first direction,
the fourth silicon carbide regions intersect the second silicon carbide regions,
the sixth silicon carbide regions extend in the first direction,
the sixth silicon carbide regions intersect the fifth silicon carbide regions, and
the fourth silicon carbide regions, the sixth silicon carbide regions, and the seventh silicon carbide regions are continuous in the first direction.

7. The semiconductor device according to claim 1, wherein a depth of the fourth silicon carbide regions is greater than a depth of the second silicon carbide regions, and
a depth of the sixth silicon carbide regions is greater than a depth of the fifth silicon carbide regions.

8. The semiconductor device according to claim 1, wherein a p-type impurity concentration in the fourth silicon carbide regions is higher than a p-type impurity concentration in the second silicon carbide regions, and
a p-type impurity concentration in the sixth silicon carbide regions is higher than a p-type impurity concentration in the fifth silicon carbide regions.

9. The semiconductor device according to claim 1, wherein a second distance in the first direction between two adjacent second portions with the fifth silicon carbide regions interposed therebetween is equal to a first distance in the first direction between two adjacent first portions with the second silicon carbide regions interposed therebetween.

10. The semiconductor device according to claim 1, wherein a width of the transistor region in the first direction is greater than a width of the diode region in the first direction.
